(19) United States
(12) Patent Application Publication
(10) Pub. No.: US 2025/0098068 A1
(43) Pub. Date: Mar. 20, 2025

(54) SEMICONDUCTOR STORAGE DEVICE AND SEMICONDUCTOR STORAGE UNIT

(71) Applicant: Kioxia Corporation, Tokyo (JP)

(72) Inventor: Kiyohito NISHIHARA, Hiratsuka Kanagawa (JP)

(21) Appl. No.: 18/884,004

(22) Filed: Sep. 12, 2024

(30) Foreign Application Priority Data
Sep. 14, 2023 (JP) 2023-149155

(51) Int. Cl. H05K 1/11; H01L 23/00; H01L 23/31; H01L 23/367; H01L 25/18; H05K 1/18; H10B 80/00

(52) U.S. Cl. CPC H05K 1/117; H01L 23/3121; H01L 23/3675; H01L 25/18; H05K 1/181; H10B 80/00; H01L 24/48; H01L 2224/48225; H01L 2924/1438; H05K 2201/09036; H05K 2201/09863; H05K 2201/10159; H05K 2201/10515; H05K 2201/10522

(57) ABSTRACT

A semiconductor storage device includes a first substrate including a first layer and a second layer on the first layer, a memory chip on the first layer, a controller disposed on the first layer and configured to control the memory chip, and molding resin that covers the first layer, the memory chip, and the controller. The second layer of the first substrate includes a conductive pattern including a plurality of terminals, and an insulating layer partially covering the conductive pattern and the first layer, and at a part of the first layer not covered by the insulating layer, one or both of the conductive pattern and the insulating layer form first concaves at predetermined intervals.

### CROSS-REFERENCE TO RELATED APPLICATIONS

This application is based upon and claims the benefit of priority from Japanese Patent Application No. 2023-149155, filed Sep. 14, 2023, the entire contents of which are incorporated herein by reference.

### FIELD

Embodiments described herein relate generally to a semiconductor storage device and a semiconductor storage unit.

### BACKGROUND

A semiconductor storage device that includes a substrate, a memory chip mounted on a first surface of the substrate, and a plurality of terminals provided on a second surface of the substrate has been known.

### BRIEF DESCRIPTION OF THE DRAWINGS

FIG. 1 shows a configuration of a semiconductor storage unit in a first embodiment.

FIG. 2 is a sectional view of a semiconductor storage device in the first embodiment.

FIG. 3 is a diagram illustrating a surface layer of a substrate in the first embodiment.

FIG. 4 is a sectional view of a thermal conductive sheet in the first embodiment.

FIG. 5 is a plan view of a substrate of a host device in the first embodiment.

FIG. 6 is a perspective view showing a first state of the semiconductor storage device attached to a connector in the first embodiment.

FIG. 7 is a perspective view showing a second state when the semiconductor storage device in the first embodiment is attached.

FIG. 8 is a perspective view showing a third state when the semiconductor storage device in the first embodiment is attached.

FIG. 9 is a sectional view showing a method of manufacturing the semiconductor storage device in the first embodiment.

FIG. 10 shows a semiconductor storage device in a first modified example of the first embodiment.

FIG. 11 shows a semiconductor storage device in a second modified example of the first embodiment.

FIG. 12 is a sectional view showing a method of manufacturing the semiconductor storage device in the second modified example of the first embodiment.

FIG. 13 shows a semiconductor storage device in a third modified example of the first embodiment.

FIG. 14 shows a semiconductor storage device in a second embodiment.

FIG. 15 shows a semiconductor storage device in a first modified example of the second embodiment.

FIG. 16 shows a semiconductor storage device in a second modified example of the second embodiment.

FIG. 17 shows a semiconductor storage device in a third embodiment.

FIG. 18 shows a semiconductor storage device in a first modified example of the third embodiment.

FIG. 19 shows a semiconductor storage device in a second modified example of the third embodiment.

FIG. 20 shows a semiconductor storage device in a fourth embodiment.

FIG. 21 shows a semiconductor storage device in a first modified example of the fourth embodiment.

FIG. 22 shows a semiconductor storage device in a second modified example of the fourth embodiment.

FIG. 23 shows a semiconductor storage device in a modified example of the first to fourth embodiments.

### DETAILED DESCRIPTION

One embodiment provides a semiconductor storage device and a semiconductor storage unit that can facilitate improvement in heat dissipation.

In general, according to one embodiment, a semiconductor storage device, comprises a first substrate including a first layer and a second layer on the first layer; a memory chip on the first layer; a controller disposed on the first layer and configured to control the memory chip; and molding resin that covers the first layer, the memory chip, and the controller. The second layer of the first substrate includes: a conductive pattern including a plurality of terminals, and an insulating layer partially covering the conductive pattern and the first layer. At a part of the first layer not covered by the insulating layer, one or both of the conductive pattern and the insulating layer form first concaves at predetermined intervals.

Hereinafter, semiconductor storage devices and semiconductor storage units according to embodiments are described with reference to the drawings. In the following description, components having the same or similar functions are assigned the identical symbols. Redundant description of these components is sometimes omitted. In the present application, the terms are defined as follows. “Parallel”, “orthogonal”, or “same/identical” can respectively involve “substantially parallel”, “substantially orthogonal”, or “substantially same/identical”. “Connection” is not limited to mechanical connection but can also involve electrical connection. That is, “connection” is not only limited to a case where two elements as connection targets are directly connected to each other but also can involve a case where two elements as connection targets are connected to each other via another element intervening therebetween. Furthermore, “connection” is not only limited to a coupled case but can also involve a case of only being in contact.

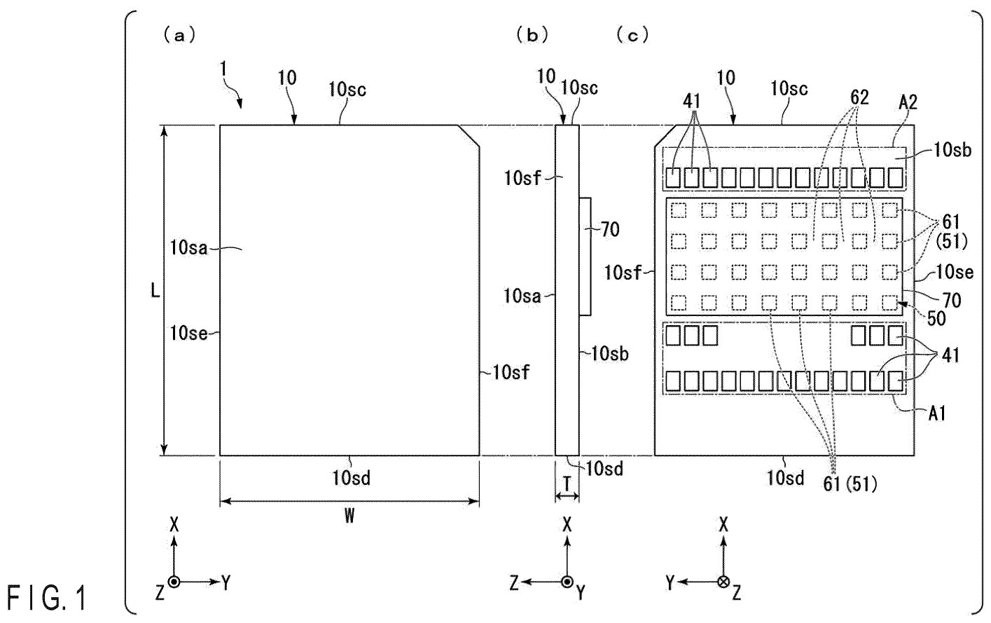

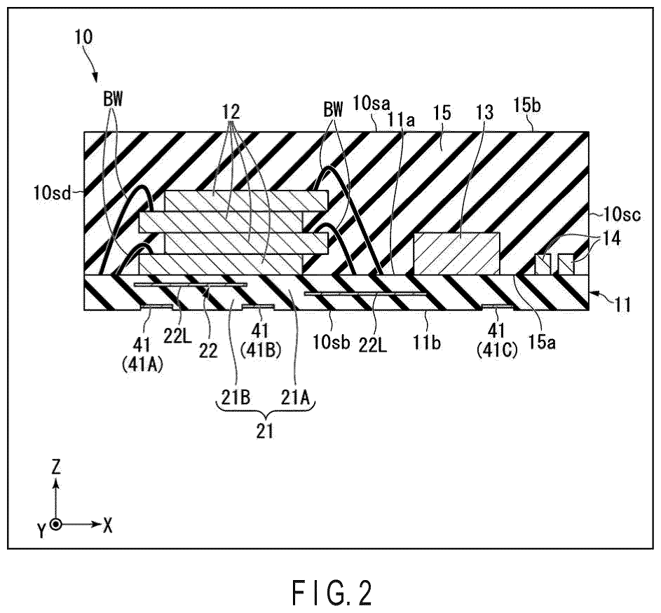

An X-direction, a Y-direction, and a Z-direction are defined as follows. The X- and Y-directions are directions along an after-mentioned first surface 11a (see FIG. 2) of a substrate 11. The X-direction is a direction from a first area A1 to a second area A2, described later (see FIG. 1). The Y-direction is a direction intersecting with (for example, orthogonal to) the X-direction. The Z-direction is a direction intersecting with (for example, orthogonal to) the X- and Y-directions. The Z-direction is, for example, the thickness direction of the substrate 11.

In the drawings described below, the content of a part accompanied by characters “b-b section” indicates a section taken along line b-b shown in (a) of the corresponding drawing, the content of a part accompanied by characters “c-c section” indicates a section taken along line c-c shown in (a) of the corresponding drawing, and the content of a part accompanied by characters “d-d section” indicates a section taken along line d-d shown in (a) of the corresponding drawing.

### First Embodiment

### <1. Configuration of Semiconductor Storage Unit>

FIG. 1 shows a configuration of a semiconductor storage unit 1 in a first embodiment. FIG. 1(a) shows a surface on one side of the semiconductor storage unit 1. FIG. 1(b) shows a surface on another side of the semiconductor storage unit 1. FIG. 1(c) shows a surface on yet another side of the semiconductor storage unit 1. The semiconductor storage unit 1 includes, for example, a semiconductor storage device 10 and a thermal conductive sheet 70.

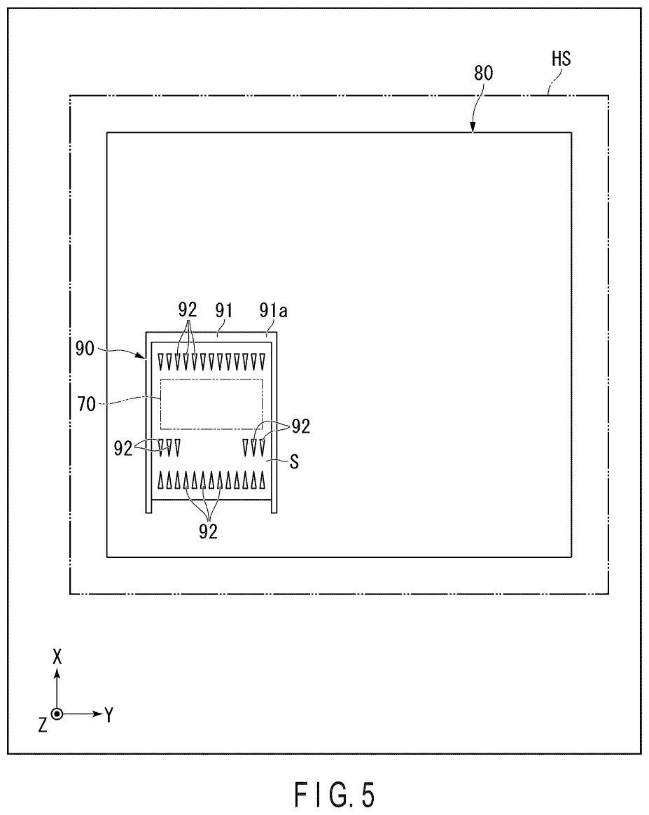

The semiconductor storage device 10 is, for example, an SSD (Solid State Drive). The semiconductor storage device 10 has, for example, an SiP (System in Package) structure. The semiconductor storage device 10 is attached to a host device, and is used as a storage of the host device. The host device is a personal computer, a mobile device, a video recorder, or a vehicle-mounted device, but is not limited to such examples. Hereinafter, an example where the semiconductor storage device 10 is attached to a host device HS (see FIG. 5) is described.

The semiconductor storage device 10 is, for example, a card-type semiconductor storage device, such as a memory card. For example, the semiconductor storage device 10 has a length L in the X-direction, a width W in the Y-direction, and a thickness T in the Z-direction. The length L is longer than the width W. An example of the length L is 18 mm±0.10 mm. An example of the width W is 14 mm±0.10 mm. An example of the thickness Tis 1.4 mm±0.10 mm. Note that the specifications and numerical values described above do not limit the present embodiment.

As shown in FIG. 1, the semiconductor storage device 10 includes a first principal surface 10sa, a second principal surface 10sb, a first end surface 10sc, a second end surface 10sd, a first side surface 10se, and a second side surface 10sf.

The first principal surface 10sa and the second principal surface 10sb are the largest surfaces among the six surfaces described above. The second principal surface 10sb is positioned on the opposite side of the first principal surface 10sa. The first principal surface 10sa and the second principal surface 10sb are apart from each other in the Z-direction, and extend in the X- and Y-directions.

The first end surface 10sc and the second end surface 10sd are apart from each other in the X-direction, and extend in the Y- and Z-directions. The first end surface 10sc connects one end of the first principal surface 10sa in the X-direction, and one end of the second principal surface 10sb in the X-direction to each other. The second end surface 10sd connects the other end of the first principal surface 10sa in the X-direction, and the other end of the second principal surface 10sb in the X-direction to each other.

The first side surface 10se and the second side surface 10sf are apart from each other in the Y-direction, and extend in the X- and Z-directions. The first side surface 10se connects one end of the first principal surface 10sa in the Y-direction, and one end of the second principal surface 10sb in the Y-direction to each other. The second side surface 10sf connects the other end of the first principal surface 10sa in the Y-direction, and the other end of the second principal surface 10sb in the Y-direction to each other.

### <2. Configuration of Semiconductor Storage>

Next, a configuration of the semiconductor storage device 10 is described.

FIG. 2 is a sectional view of the semiconductor storage device 10. The semiconductor storage device 10 includes, for example, the substrate 11, one or more (e.g., a plurality of) memory chips 12, a controller 13, one or more (e.g., a plurality of) electronic components 14, and molding resin 15.

### <2.1 Substrate>

The substrate 11 is a printed circuit board. The substrate 11 has a plate-like shape that extends in the X- and Y-directions. The substrate 11 includes a first surface 11a and a second surface 11b. The first surface 11a and the second surface 11b are apart from each other in the Z-direction, and extend in the X- and Y-directions. The first surface 11a is a surface covered with the molding resin 15 when viewed from the Z-direction. The second surface 11b is positioned on the opposite side of the first surface 11a. The second surface 11b is exposed outside of the semiconductor storage device 10. The second surface 11b forms the second principal surface 10sb of the semiconductor storage device 10.

### <2.2 Memory Chip>

Each memory chip 12 is a semiconductor memory chip that stores data in a non-volatile manner. Each memory chip 12 is, for example, a NAND flash memory. Note that “semiconductor memory” is not limited to a NAND flash memory, and may be another type of memory, such as a NOR memory, an MRAM (Magnetoresistive Random Access Memory), or a resistive random access memory. The memory chips 12 produce heat when the semiconductor storage device 10 is used.

The memory chips 12 are disposed between the first surface 11a of the substrate 11 and the molding resin 15. For example, the plurality of memory chips 12 are stacked on top of each other, and mounted on the first surface 11a of the substrate 11. Note that the memory chips 12 may be stacked above the controller 13 from a side away from the substrate 11, instead of being mounted on the first surface 11a of the substrate 11. For example, the plurality of memory chips 12 are electrically connected to the first surface 11a of the substrate 11 through bonding wires BW.

### <2.3 Controller>

The controller 13 is a control component mounted on the substrate 11. The controller 13 integrally controls the entire semiconductor storage device 10. The controller 13 controls a writing operation to, a reading operation from, or another operation with the plurality of memory chips 12. The controller 13 is, for example, a controller chip in which functional sections for control are integrated in a single semiconductor chip. The controller 13 is, for example, a semiconductor package which includes an SoC (System on a Chip) and in which a host interface circuit communicating with the host device, a control circuit controlling the plurality of memory chips 12, a control circuit controlling a DRAM, not shown, and the like are integrated in a single semiconductor chip. The controller 13 is disposed between the first surface 11a of the substrate 11 and the molding resin 15. The controller 13 is mounted on, for example, the first surface 11a of the substrate 11. In the present embodiment, the controller 13 is disposed between the first end surface 10sc and the memory chips 12 of the semiconductor storage device 10 in the X-direction. The controller 13 produces heat when the semiconductor storage device 10 is used.

### <2.4 Electronic Components>

The electronic components 14 are mounted on, for example, the first surface 11a of the substrate 11. The electronic components 14 are capacitors, resistors, etc.

### <2.5 Molding Resin>

The molding resin 15 is an encapsulation member provided on and covering the first surface 11a of the substrate 11. The molding resin 15 is formed of an insulating material. The molding resin 15 integrally encapsulates, for example, the plurality of memory chips 12, the controller 13, and the plurality of electronic components 14.

The molding resin 15 includes a first surface 15a and a second surface 15b. The first surface 15a is in contact with the first surface 11a of the substrate 11. The second surface 15b is positioned on the opposite side of the first surface 15a. The second surface 15b extends along the X- and Y-directions. The second surface 15b forms the first principal surface 10sa of the semiconductor storage device 10.

### <3. Configuration of Substrate>

Next, the configuration of the substrate 11 is described.

As shown in FIG. 2, the substrate 11 is, for example, a multi-layered circuit board. The substrate 11 includes an insulating base material 21, and a wiring pattern 22.

The insulating base material 21 is an insulative material that forms a base of the substrate 11. The insulating base material 21 is formed of, for example, a rigid insulating material, such as a glass epoxy material. Note that the material of the insulating base material 21 is not limited to that in the example described above. The insulating base material 21 may be formed of a paper phenol material, a composite material, a fluorine resin material, a polyimide material or the like.

In the present embodiment, the insulating base material 21 includes a core material 21A, and a prepreg 21B stacked on the core material 21A. The prepreg 21B is positioned closer to the second surface 11b than the core material 21A. Note that the substrate 11 is not limited to a multi-layered circuit board, and may be a double-sided substrate instead. That is, the insulating base material 21 may be made solely of the core material 21A without including the prepreg 21B. Accordingly, in the following description, the “insulating base material 21” may be read as the “core material 21A”, and a “surface 21s of the insulating base material 21” may be read as a “surface 21s of the core material 21A”.

The wiring pattern 22 is a conductive part provided on the substrate 11. The wiring pattern 22 includes wires 22L provided in the insulating base material 21 and/or on the surface of the substrate 11. The wiring pattern 22 is formed of, for example, a metal material, such as copper.

### <4. Configuration of Surface Layer of Substrate>

Next, a surface layer 30 of the substrate 11 is described.

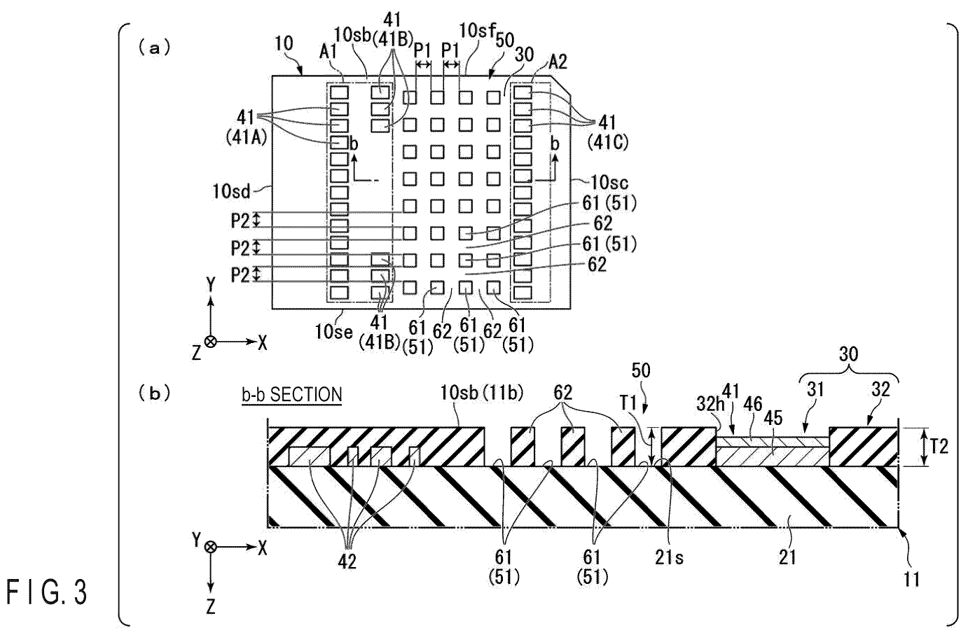

FIG. 3 is a diagram illustrating the surface layer 30 of the substrate 11. As shown in FIG. 3, the substrate 11 includes the surface layer 30. The surface layer 30 is a part that is stacked on the insulating base material 21, and forms the second surface 11b of the substrate 11. The surface layer 30 includes a conductive pattern 31 and a solder resist layer 32.

Here, the semiconductor storage device 10 includes a first area A1 and a second area A2. The first area A1 is disposed between the center of the semiconductor storage device 10 in the X-direction, and the second end surface 10sd. A plurality of terminals 41A and 41B described later are disposed in the first area A1. The second area A2 is disposed between the center of the semiconductor storage device 10 in the X-direction, and the first end surface 10sc. A plurality of terminals 41C described later are disposed in the second area A2.

### <4.1 Conductive Pattern>

The conductive pattern 31 is a conductive part included, as a part of the wiring pattern 22, in the surface layer 30. The conductive pattern 31 includes a plurality of terminals 41 and a plurality of wires 42.

### (Plurality of Terminals)

The plurality of terminals 41 are exposed to the outside of the semiconductor storage device 10 for allowing electrical connection to the host device. Each terminal 41 is, for example, a pad formed to have a planar shape along the X- and Y-directions. The plurality of terminals 41 are provided, for example, on the surface 21s of the insulating base material 21. Each terminal 41 is exposed to the outside of the semiconductor storage device 10 via an opening 32h of the solder resist layer 32. Each of the terminals 41 is, for example, a signal terminal, a power source terminal, or a ground terminal. Note that some of the terminals 41 may be test terminals.

Each terminal 41 includes a main body 45, and a protective film 46. The main body 45 is formed of, for example, a metal material, such as copper. The protective film 46 is stacked on the main body 45 from a side away from the insulating base material 21. The protective film 46 is, for example, a plating layer provided for preventing rust. The protective film 46 is formed of, for example, a metal material, such as gold or nickel.

The plurality of terminals 41 include a plurality of terminals 41A and 41B arranged in the first area A1, and a plurality of terminals 41C arranged in the second area A2.

The plurality of terminals 41A are arranged in a single row in the Y-direction. The plurality of terminals 41B are arranged between the plurality of terminals 41A and the plurality of terminals 41C in the X-direction. The plurality of terminals 41B include three terminals 41B (i.e., three terminals 41B closer to the first side surface) arranged between the center of the semiconductor storage device 10 in the Y-direction and the first side surface 10se, and three terminals 41B (i.e., three terminals 41B closer to the second side surface) arranged between the center of the semiconductor storage device 10 in the Y-direction and the second side surface 10sf. The three terminals 41B closer to the first side surface and the three terminals 41B closer to the second side surface are arranged in a single row in the Y-direction.

The plurality of terminals 41C are arranged in a single row in the Y-direction. The distance between the plurality of terminals 41C and the plurality of terminals 41B in the X-direction is larger than the distance between the plurality of terminals 41A and the plurality of terminals 41B in the X-direction.

### (Plurality of Wires)

The plurality of wires 42 are wires included, as parts of the wires 22L, in the surface layer 30. The plurality of wires 42 are provided on the surface 21s of the insulating base material 21. At least some of the wires 42 are electrically connected to the terminals 41.

### <4.2 Solder Resist Layer>

The solder resist layer 32 is an insulating protective layer that protects the conductive pattern 31. The solder resist layer 32 is provided, for example, on the surface 21s of the insulating base material. The solder resist layer 32 has the openings 32h allowing the respective terminals 41 to be exposed, and cover a part of the conductive pattern 31. For example, the solder resist layer 32 covers the plurality of wires 42.

### <5. Non-Planar Part>

Next, the non-planar part 50 of the surface layer 30 is described.

As shown in FIG. 3, the surface layer 30 includes the non-planar part 50. When viewed from the Z-direction, the non-planar part 50 is provided in an area of the surface layer 30 outside of the plurality of terminals 41. In the present embodiment, the non-planar part 50 is provided between the first area A1 and the second area A2 in the X-direction.

In the present embodiment, the non-planar part 50 includes a plurality of recesses 51. The plurality of recesses 51 are arranged in a matrix manner including, for example, four rows in the X-direction and eight rows in the Y-direction. The recesses 51 are blind holes provided in the solder resist layer 32. Each recess 51 reaches a position closer to the insulating base material 21 than a part of the terminal 41 in the Z-direction. For example, the recess 51 reaches the surface 21s of the insulating base material 21 (e.g., the surface of the core material 21A). In the present embodiment, the plurality of recesses 51 described above are provided, which allows the non-planar part 50 to have an irregular structure where concaves 61 and convexes 62 are alternately arranged. For example, the concaves 61 and the convexes 62 are alternately arranged in the X- and Y-directions.

In the present embodiment, it is preferable that the non-planar part 50 be formed at a location on the surface layer 30 that is close to the controller 13 and/or the memory chips 12 that have high heat generation. For example, at least a part of the non-planar part 50 is provided in an area of the surface layer 30 that overlaps the controller 13 when viewed from the Z-direction. For example, at least a part of the non-planar part 50 is provided in an area of the surface layer 30 that overlaps the memory chips 12 when viewed from the Z-direction.

### <5.1 Shape of Concave>

The concaves 61 are formed of the recesses 51. In other words, in the present embodiment, the “concaves 61” may be read as the “recesses 51”. The plurality of concaves 61 are arranged equally in the X-direction at an interval P1. The width of the concave 61 in the X-direction is, for example, equivalent to the interval P1 or more. The width of the concave 61 in the X-direction is, for example, smaller than the width of the terminal 41 in the X-direction. The plurality of concaves 61 are arranged equally in the Y-direction at an interval P2. The width of the concave 61 in the Y-direction is, for example, equivalent to the interval P2 or more. The width of the concave 61 in the Y-direction is, for example, smaller than the width of the terminal 41 in the Y-direction. Note that the width of the concave 61 in the X-direction may be larger than the width of the terminal 41 in the X-direction. The width of the concave 61 in the Y-direction may be larger than the width of the terminal 41 in the Y-direction.

Each concave 61 reaches a position closer to the insulating base material 21 than a part of the terminal 41 in the Z-direction. For example, the concave 61 reaches the surface 21s of the insulating base material 21 (e.g., the surface of the core material 21A). The concave 61 has a polygonal shape when viewed from the Z-direction. In the present embodiment, the concave 61 has a quadrangular shape when viewed from the Z-direction. Note that the concave 61 may have a polygonal shape, such as of triangular or pentagonal or more, or a circular shape. For example, in a case where each concave 61 has a polygonal shape of pentagonal or more, or a circular shape, a part of an after-mentioned thermal conductive sheet 70 tends to enter the inside of each concave 61, and it is easy to secure a more contact area between the non-planar part 50 and the thermal conductive sheet 70.

### <5.2 Shape of Convex>

The convexes 62 are parts each formed between two concaves 61 adjacent to each other by providing the plurality of concaves 61. Each “convex” in the present application means a part protruding in the direction away from the insulating base material 21 in comparison with the bottom of the concave. In the present embodiment, each convex 62 is formed between two concaves 61 adjacent to each other in the X-direction or the Y-direction. For example, each convex 62 is a remaining part of the solder resist layer 32 that resides between the two concaves 61 adjacent to each other. In the present embodiment, the convexes 62 are formed of the same insulating material as that of the solder resist layer 32. In the present embodiment, a thickness (i.e., protruding height) T1 of the convex 62 from the surface 21s of the insulating base material 21 in the Z-direction is the same as, for example, a thickness T2 of the solder resist layer 32 from the surface 21s of the insulating base material 21 in the Z-direction.

The thickness T1 of the convex 62 in the Z-direction (or the thickness T2 of the solder resist layer 32 in the Z-direction) is, for example, several micrometers to several millimeters. Further specifically, the thickness T1 of the convex 62 in the Z-direction (or the thickness T2 of the solder resist layer 32 in the Z-direction) is, for example, 10 μm or more. The thickness T1 of the convex 62 in the Z-direction (or the thickness T2 of the solder resist layer 32 in the Z-direction) is, for example, 30 μm or less.

In the present embodiment, the convexes 62 extend in a direction parallel to the second surface 11b of the substrate 11. For example, the convexes 62 linearly extend in the X-direction or the Y-direction. For example, the plurality of convexes 62 include: three convexes 62 that are apart from each other in the X-direction, and extend in the Y-direction; and seven convexes 62 that are apart from each other in the Y-direction, and extend in the X-direction. Each of three convexes 62 extends so as to pass adjacent to the plurality of concaves 61, and across the non-planar part 50 in the Y-direction. Each of seven convexes 62 extends so as to pass adjacent to the plurality of concaves 61, and across the non-planar part 50 in the X-direction. Each of the three convexes 62 reaches the opposite ends of the semiconductor storage device 10 in the Y-direction. Each of the seven convexes 62 reaches both the first area A1 and the second area A2 of the semiconductor storage device 10. At each of intersections between the three convexes 62 and the seven convexes 62, a connection part where the convexes 62 extending in the X-direction and the convexes 62 extending in the Y-direction are connected to each other so as to crisscross is formed.

### <6. Thermal Conductive Sheet>

Next, returning to FIG. 1, the thermal conductive sheet 70 is described. The thermal conductive sheet 70 is, for example, a sheet that has a higher thermal conductivity than the solder resist layer 32 does. The thermal conductive sheet 70 has, for example, a thermal conductivity of 1.0 W/(m·K) or higher. The thermal conductive sheet 70 is formed of, for example, silicone. The thermal conductive sheet 70 is disposed to overlap the non-planar part 50 when viewed from the Z-direction, and is in contact with the non-planar part 50. For example, the thermal conductive sheet 70 has an external shape that covers the entire area of the non-planar part 50 when viewed from the Z-direction. Note that the thermal conductive sheet 70 is not necessarily fixed to the semiconductor storage device 10, and may only be in contact with the non-planar part 50.

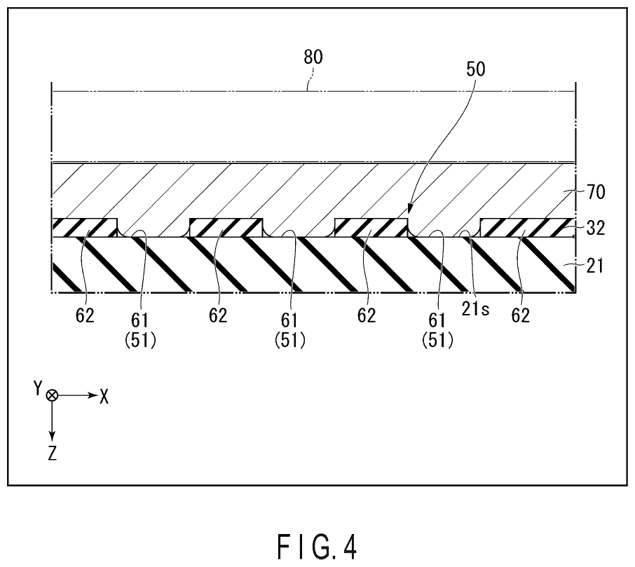

FIG. 4 is a sectional view of the thermal conductive sheet 70. The thermal conductive sheet 70 has sufficient flexibility such that a part of the thermal conductive sheet 70 enters the openings of the concaves 61 and the thermal conductive sheet 70 is pressed at least against the non-planar part 50. The thermal conductive sheet 70 is in contact with the inner surfaces of the concaves 61 (i.e., the side surfaces of the convexes 62) by a part of this thermal conductive sheet 70 entering the openings of the concaves 61. The thermal conductive sheet 70 is in contact with the bottom surfaces of the concaves 61 (i.e., the surface 21s of the insulating base material 21) by a part of the thermal conductive sheet 70 entering the openings of the concaves 61.

### <7. Connector of Host Device>

Next, the connector 60 of the host device HS is described.

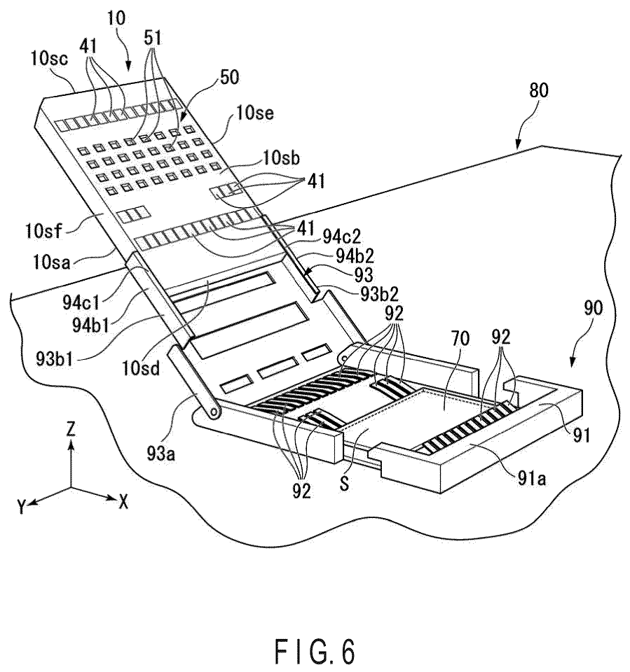

FIG. 5 is a plan view of a substrate 80 of the host device HS. Hereinafter, for convenience of illustration, the substrate 80 of the host device HS is called “host substrate 80”. The host substrate 80 includes a connector 90 of a socket type (e.g., a clamshell socket type). The semiconductor storage device 10 is manually attachable to the connector 90 in a removable manner. For example, the semiconductor storage device 10 can be removed from the connector 90 and easily replaced in case of a failure. The connector 90 includes, for example, a connector main body 91, a plurality of terminals 92, and a holder 93 (see FIG. 6).

### (Connector Main Body)

The connector main body 91 is a main part of the external shape of the connector 90. The connector main body 91 is fixed to the host substrate 80. The connector main body 91 is electrically connected to the host substrate 80. The connector main body 91 includes a housing S that can house the semiconductor storage device 10. The connector main body 91 includes, for example, a wall 91a one side of which in the X-direction is open and which surrounds the housing S from the three directions.

### (Plurality of Terminals)

The plurality of terminals 92 are exposed to the outside of the connector 90 in order to be connected to the plurality of terminals 41 of the semiconductor storage device 10. The plurality of terminals 92 are arranged at positions for one-to-one correspondence with the respective terminals 41 of the semiconductor storage device 10. Each terminal 92 is a pin-type terminal that has a shape elongated in the X-direction.

A base end of each terminal 92 is connected to the connector main body 91, and is supported by the connector main body 91. Each terminal 92 is electrically connected to the host substrate 80 via the connector main body 91. A distal end of each terminal 92 is positioned at a height floating from the host substrate 80 (see FIG. 6). Each terminal 92 is disposed to be inclined from the surface of the host substrate 80 so that the distal end of the terminal 92 can be apart from the host substrate 80 in comparison with the base end. Each terminal 92 is made of metal, and is elastically deformable. In the present embodiment, after the semiconductor storage device 10 is attached to the connector 90, each terminal 92 is pressed by the semiconductor storage device 10 against the host substrate 80. Thus, each terminal 92 is elastically deformed. As a result, the distal end of each terminal 92 is in close contact with the corresponding terminal 41 of the semiconductor storage device 10 by the restoring force of the elastic deformation.

### (Holder)

FIG. 6 is a perspective view showing a first state of the semiconductor storage device 10 attached to the connector 90. The holder 93 holds the semiconductor storage device 10 when the semiconductor storage device 10 is attached to the connector 90. The holder 93 is rotatably coupled to the connector main body 91. The holder 93 includes, for example, a base end 93a, a first supporter 93b1, and a second supporter 93b2.

The base end 93a has a hinge structure, and is rotatably coupled to an end of the connector main body 91. The first supporter 93b1 and the second supporter 93b2 are apart from each other in the Y-direction, and extend in a direction away from the base end 93a.

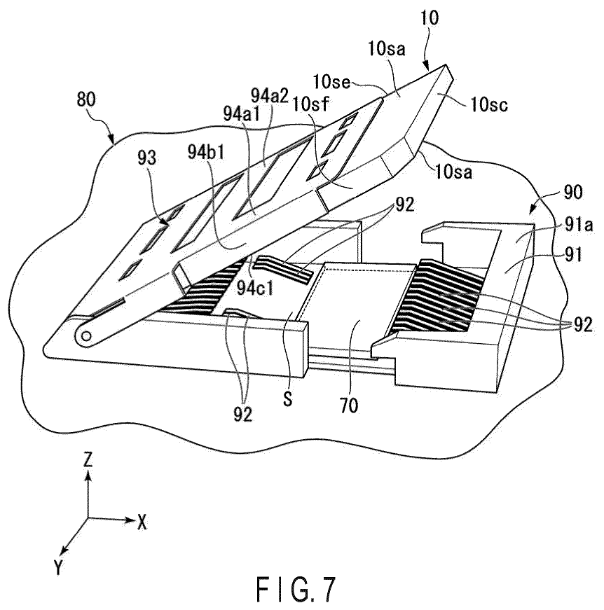

The first supporter 93b1 includes: a first part 94al along the first principal surface 10sa of the semiconductor storage device 10 (see FIG. 7); a second part 94b1 along the first side surface 10se of the semiconductor storage device 10; and a third part 94cl reaching the second principal surface 10sb of the semiconductor storage device 10. Likewise, the second supporter 93b2 includes: a first part 94a2 along the first principal surface 10sa of the semiconductor storage device 10 (see FIG. 7); a second part 94b2 along the second side surface 10sf of the semiconductor storage device 10; and a third part 94c2 reaching the second principal surface 10sb of the semiconductor storage device 10. The semiconductor storage device 10 is inserted between the first supporter 93b1 and the second supporter 93b2, thus being attached to the holder 93.

Note that in this case, the thermal conductive sheet 70 may be attached to the semiconductor storage device 10, or attached to the host substrate 80. Hereinafter, an example where the thermal conductive sheet 70 is attached to the host substrate 80 is described.

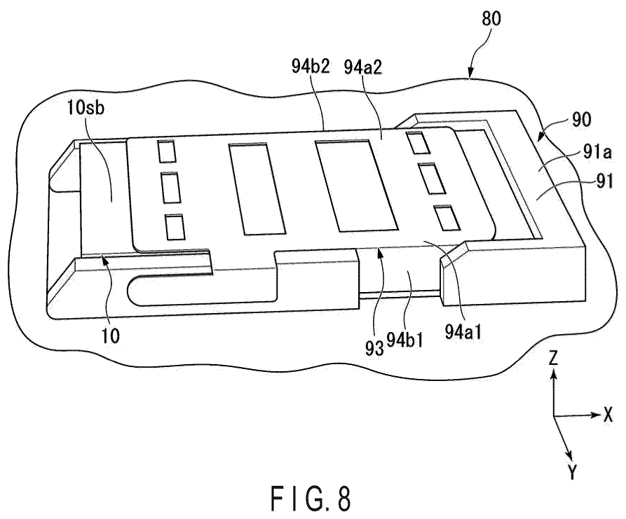

FIG. 7 is a perspective view showing a second state of the semiconductor storage device 10 attached to the connector 90. In the second state, the holder 93 is turned or rotated toward the host substrate 80 from the first state. FIG. 8 is a perspective view showing a third state of the semiconductor storage device 10 attached to the connector 90. In the third state, the holder 93 is further rotated toward the host substrate 80 from the second state, and the semiconductor storage device 10 is housed in the housing S (see FIG. 7) of the connector main body 91.

Accordingly, after the semiconductor storage device 10 is attached to the holder 93 and subsequently the holder 93 is rotated toward the host substrate 80, the semiconductor storage device 10 is removably attached to the connector 90 in a state where the thermal conductive sheet 70 intervenes between the non-planar part 50 and the host substrate 80.

### <8. Manufacturing Method>

Next, a method of manufacturing the semiconductor storage device 10 is described.

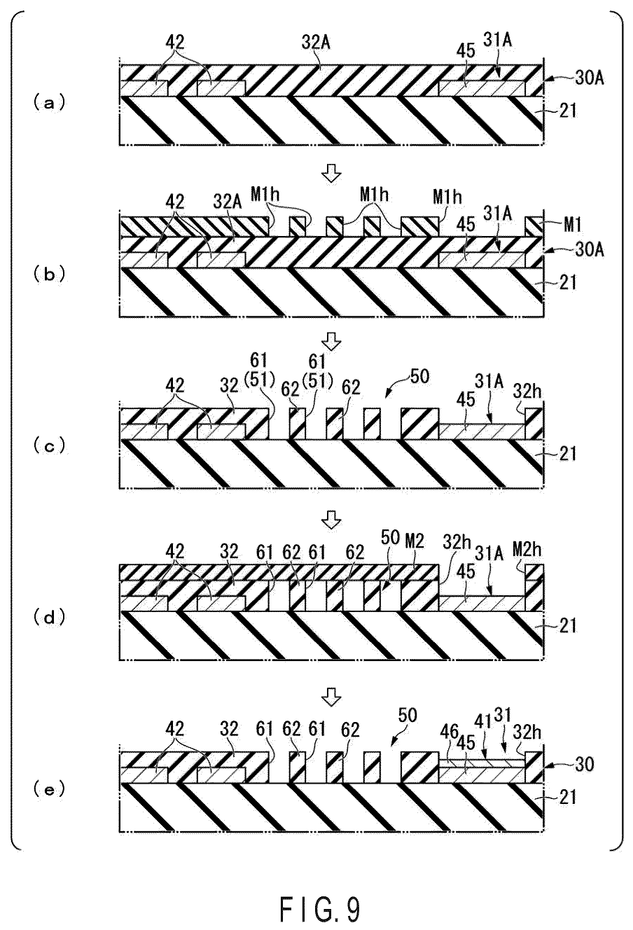

FIG. 9 includes sectional views showing the method of manufacturing the semiconductor storage device 10. First, as shown in FIG. 9(a), a surface layer 30A is formed on the insulating base material 21. The surface layer 30A includes: a conductive pattern 31A provided on the insulating base material 21; and a solder resist layer 32A that covers the entire conductive pattern 31A. The conductive pattern 31A includes a main body 45 of the terminal 41, and a plurality of wires 42.

Next, as shown in FIG. 9(b), a mask M1 is formed on the solder resist layer 32A. The mask M1 has openings M1h at positions corresponding to the openings 32h in the solder resist layer 32 and the plurality of recesses 51. Next, as shown in FIG. 9(c), etching is performed using the mask M1, which forms a plurality of recesses 51 that form the concaves 61 and the convexes 62, and the openings 32h. Thus, the solder resist layer 32 is formed from the solder resist layer 32A.

Next, as shown in FIG. 9(d), a mask M2 is formed on the solder resist layer 32 by, for example, dry film lamination. The mask M2 covers the non-planar part 50, and has openings M2h at positions corresponding to the respective openings 32h in the solder resist layer 32. Next, as shown in FIG. 9(e), a plating process is performed through the openings M2h in the mask M2. Thus, the terminals 41 are formed.

### <9. Advantages>

As a comparative example, a case where the surface of the semiconductor storage has a planar shape is considered. In this case, the heat dissipation area is small, and it is difficult to expect increase of a certain rate of heat dissipation or higher.

On the other hand, in the present embodiment, the substrate 11 includes the surface layer 30 forming the second surface 11b of the substrate 11. The surface layer 30 includes: the conductive pattern 31 that includes the plurality of terminals 41 exposed to the outside; and the solder resist layer 32 that covers a part of the conductive pattern 31. The surface layer 30 includes the non-planar part 50 which includes the plurality of recesses 51 in an area outside of the plurality of terminals 41 and in which concaves 61 and the convexes 62 are alternately arranged. According to such a configuration, the alternately arranged concaves 61 and convexes 62 increase the heat dissipation area of the semiconductor storage device 10. This can facilitate improvement in heat dissipation of the semiconductor storage device 10. Note that irrespective of presence or absence of the thermal conductive sheet 70, the semiconductor storage device 10 can improve the heat dissipation in comparison with a semiconductor storage having a planar surface.

In the present embodiment, the semiconductor storage device 10 is used in combination with the thermal conductive sheet 70 overlaid on the non-planar part 50. According to such a configuration, a part of the thermal conductive sheet 70 is in contact with the inner surfaces of the concaves 61, which can increase the contact area between the semiconductor storage device 10 and the thermal conductive sheet 70. This can facilitate further improvement in heat dissipation of the semiconductor storage device 10.

In the present embodiment, the semiconductor storage device 10 can be attached to the connector 90 in a removable manner in the state where the thermal conductive sheet 70 intervenes between the non-planar part 50 and the host substrate 80. According to such a configuration, heat transmitted from the non-planar part 50 to the thermal conductive sheet 70 can be dissipated through the host substrate 80. This can facilitate further improvement in heat dissipation of the semiconductor storage device 10.

In the present embodiment, the connector 90 includes: the connector main body 91 fixed to the host substrate 80; and the holder 93 rotatable with respect to the connector main body 91. After the semiconductor storage device 10 is attached to the holder 93 and subsequently the holder 93 is rotated toward the host substrate 80, the semiconductor storage device 10 can be electrically connected to the connector 90 in the state where the thermal conductive sheet 70 intervenes between the non-planar part 50 and the host substrate 80. According to such a configuration, the semiconductor storage device 10 is attached to the holder 93 of the connector 90, and an operation of rotating the holder 93 can allow the thermal conductive sheet 70 to intervene between the non-planar part 50 and the host substrate 80. Thus, the non-planar part 50 and the thermal conductive sheet 70 can be more easily brought into close contact.

In the present embodiment, the substrate 11 includes the insulating base material 21. The conductive pattern 31 includes the wires 42 provided on the surface 21s of the insulating base material 21. The concaves 61 reach the surface 21s of the insulating base material 21. According to such a configuration, the heat dissipation rate from the surface 21s of the insulating base material 21 (e.g., the core material 21A), which is closer to the heat source, can be increased. This can facilitate further improvement in heat dissipation of the semiconductor storage device 10. Furthermore, according to the configuration described above, relatively deep concaves can be formed as the concaves 61. Thus, the contact area between the semiconductor storage device 10 and the thermal conductive sheet 70 can be further increased, which can further facilitate the heat dissipation of the semiconductor storage device 10.

In the present embodiment, the convexes 62 are formed of the same insulating material as that of the solder resist layer 32. According to such a configuration, the close contact property between the convexes 62 and the insulating base material 21 tends to be favorable, and the convexes 62 can be resistant to falling from the insulating base material 21. Accordingly, the reliability of the semiconductor storage device 10 can be improved.

### First Modified Example of First Embodiment

Next, a first modified example of the first embodiment is described. This modified example is different from the first embodiment in that a part of each convex is made of a metal material. Note that configuration points other than those described below are the same as the corresponding configuration points in the first embodiment. In this case, the “concaves 61” are read as “concaves 61A”, and the “convexes 62” are read as “convexes 62A”.

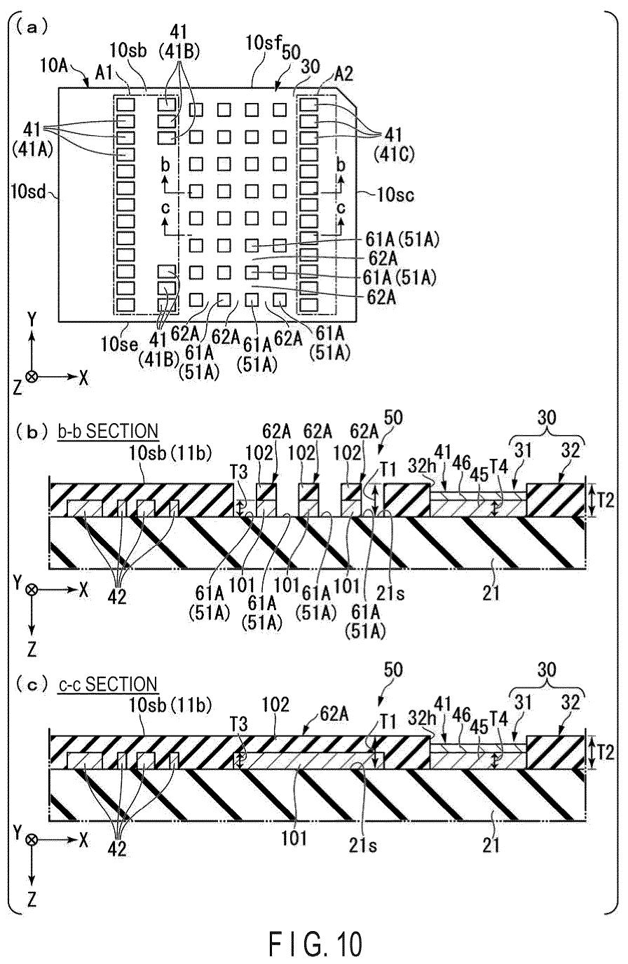

FIG. 10 shows a semiconductor storage device 10A in the first modified example of the first embodiment. The surface layer 30 of the semiconductor storage device 10A includes a plurality of recesses 51A, and thus includes a non-planar part 50 where the concaves 61A and the convexes 62A are alternately arranged. The concaves 61A are the same as the concaves 61 in the first embodiment. Each convex 62A includes a first part 101 and a second part 102.

Each first part 101 is formed of the same material as that of at least a part of the terminal 41. For example, the first part 101 is formed of the same metal material (e.g., copper) as that of the main body 45 of the terminal 41. The first parts 101 are formed at the same time as the main bodies 45 of the terminals 41 and the plurality of wires 42 in the process of forming the main bodies 45 of the terminals 41 and the plurality of wires 42 on the surface 21s of the insulating base material 21. A thickness T3 of each first part 101 is, for example, the same as a thickness T4 of the main body 45 of the terminal 41. For example, in the case where the thermal conductive sheet 70 is provided, the part of the thermal conductive sheet 70 entering the concaves 61A is contact with the first parts 101 of the convexes 62A.

The second part 102 is stacked on the first part 101 from a side away from the insulating base material 21. The second part 102 is formed of the same insulating material as that of the solder resist layer 32. For example, in the process of forming the solder resist layer 32, the second part 102 is formed at the same time as the solder resist layer 32.

Note that other aspects of each convex 62A are the same as those about each convex 62 described in the first embodiment. For example, the convex 62A linearly extends in the X-direction or the Y-direction. In the present embodiment, the plurality of convexes 62A include: three convexes 62A that are apart from each other in the X-direction, and extend in the Y-direction; and seven convexes 62A that are apart from each other in the Y-direction, and extend in the X-direction. Each of the three convexes 62A extends so as to pass adjacent to the plurality of concaves 61A, and across the non-planar part 50 in the Y-direction. In this case, the aforementioned first parts 101 and second parts 102 extend over the entire length of the corresponding convex 62A in the Y-direction. Each of the seven convexes 62A extends so as to pass adjacent to the plurality of concaves 61A, and across the non-planar part 50 in the X-direction. In this case, the aforementioned first parts 101 and second parts 102 extend over the entire length of the corresponding convex 62A in the X-direction.

According to such a configuration, each convex 62A includes the first part 101 formed of the metal material. Accordingly, heat is easily transferred from the insulating base material 21 to the convexes 62A, and heat is easily dissipated to the outside from the convexes 62A. This can facilitate further improvement in heat dissipation of the semiconductor storage device 10A. In another view, the part of the thermal conductive sheet 70 entering the concaves 61A is in contact with the first parts 101 of the convexes 62A, thus allowing heat to be transferred from the convexes 62A to the thermal conductive sheet 70. This can facilitate further improvement in heat dissipation of the semiconductor storage device 10A.

### Second Modified Example of First Embodiment

Next, a second modified example of the first embodiment is described. This modified example is different from the first embodiment in that the entire convexes are made of a metal material. Note that configuration points other than those described below are the same as the corresponding configuration points in the first embodiment. In this case, the “concaves 61” are read as “concaves 61B”, and the “convexes 62” are read as “convexes 62B”.

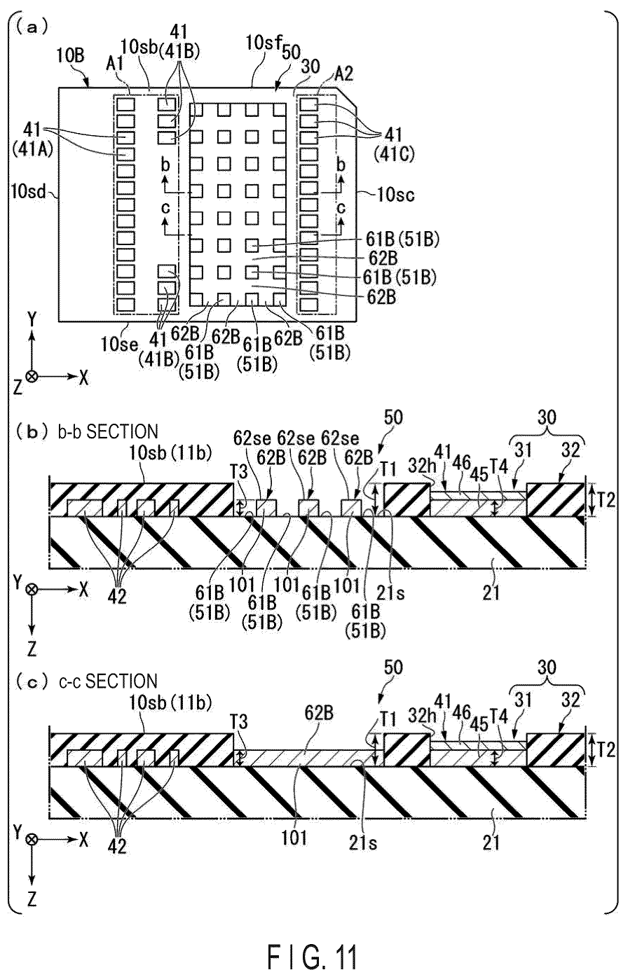

FIG. 11 shows a semiconductor storage device 10B in the second modified example of the first embodiment. The surface layer 30 of the semiconductor storage device 10B includes a plurality of recesses 51B, and thus includes a non-planar part 50 where the concaves 61B and the convexes 62B are alternately arranged. The concaves 61B are the same as the concaves 61 in the first embodiment. The convexes 62B are formed of the same metal material as that of at least a part of the terminals 41. For example, the convexes 62B are formed of the same metal material (e.g., copper) as that of the main bodies 45 of the terminals 41. The convexes 62B are formed at the same time as the main bodies 45 of the terminals 41 and the plurality of wires 42 in the process of forming the main bodies 45 of the terminals 41 and the plurality of wires 42 on the surface 21s of the insulating base material 21. The thickness T3 of each convex 62B in the Z-direction is, for example, the same as the thickness T4 of the main body 45 of each terminal 41 in the Z-direction.

In this modified example, end surfaces 62se of the convexes 62B in the Z-direction are exposed to the outside of the semiconductor storage device 10B. For example, in the case where the thermal conductive sheet 70 is provided, a part of the thermal conductive sheet 70 is in contact with the end surfaces 62se of the convexes 62B in addition to the side surfaces of the convexes 62B.

Note that other aspects of each convex 62B are the same as those about the convex 62 described in the first embodiment. For example, the convexes 62B linearly extend in the X-direction or the Y-direction. For example, the plurality of convexes 62B include: three convexes 62B that are apart from each other in the X-direction, and extend in the Y-direction; and seven convexes 62B that are apart from each other in the Y-direction, and extend in the X-direction. Each of the three convexes 62B extends so as to pass adjacent to the plurality of concaves 61, and across the non-planar part 50 in the Y-direction. Each of the seven convexes 62B extends so as to pass adjacent to the plurality of concaves 61, and across the non-planar part 50 in the X-direction.

Next, a method of manufacturing the semiconductor storage device 10B is described.

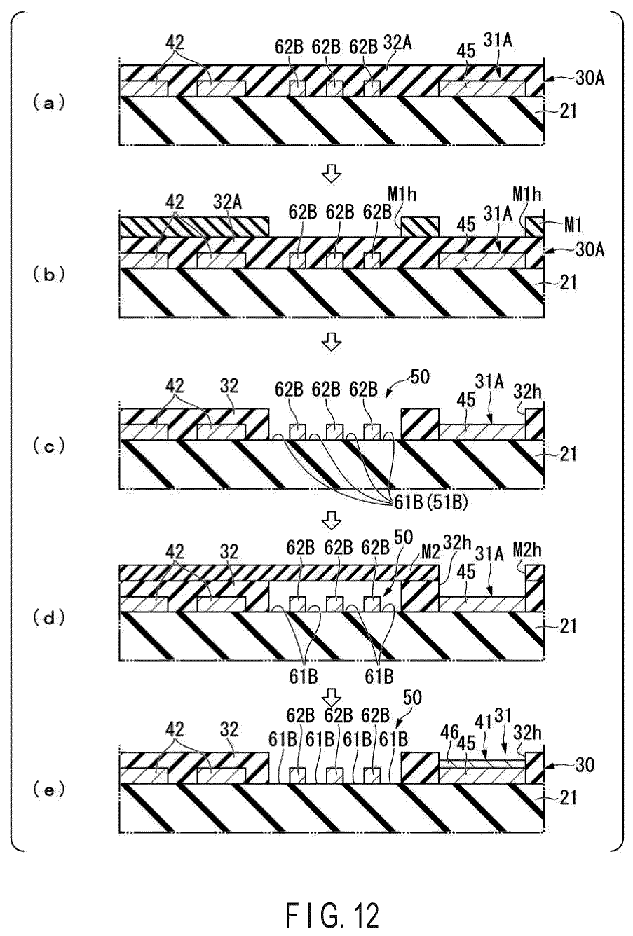

FIG. 12 includes sectional views showing the method of manufacturing the semiconductor storage device 10B. First, as shown in FIG. 12(a), a surface layer 30A is formed on the insulating base material 21. The surface layer 30A includes: a conductive pattern 31A provided on the insulating base material 21; and a solder resist layer 32A that covers the entire conductive pattern 31A. The conductive pattern 31A includes the main bodies 45 of the terminals 41, a plurality of wires 42, and the plurality of convexes 62B.

Next, as shown in FIG. 12(b), a mask M1 is formed on the solder resist layer 32A. The mask M1 has openings M1h at positions corresponding to the opening 32h in the solder resist layer 32, and the non-planar part 50. The opening M1h formed at the corresponding position of the non-planar part 50 is a large opening corresponding to the entire area of the non-planar part 50. Next, as shown in FIG. 12(c), by performing etching using the mask M1, the solder resist layer 32 is formed from the solder resist layer 32A. Thus, the plurality of convexes 62B are exposed to the outside.

Next, as shown in FIG. 12(d), a mask M2 is formed on the solder resist layer 32 by, for example, dry film lamination. The mask M2 covers the non-planar part 50, and has openings M2h at positions corresponding to the openings 32h in the solder resist layer 32. Next, as shown in FIG. 12(e), a plating process is performed through the openings M2h in the mask M2. Thus, the terminals 41 are formed.

According to such a configuration, since the convexes 62B are made of the metal material, heat is easily transferred from the insulating base material 21 to the convexes 62B, and heat is easily dissipated from the convexes 62B to the outside. This can facilitate further improvement in heat dissipation of the semiconductor storage device 10B. In another view, since the contact area between the convexes 62B made of metal and the thermal conductive sheet 70 is large, heat is easily transferred from the convexes 62B to the thermal conductive sheet 70. This can facilitate further improvement in heat dissipation of the semiconductor storage device 10B.

### Third Modified Example of First Embodiment

Next, a third modified example of the first embodiment is described. This modified example is different from the second modified example in that a protective film is formed on the surface of each convex. Note that aspects other than those described later are the same as the corresponding points in the second modified example described above. In this case, the “concaves 61B” are read as “concaves 61C”, and the “convexes 62B” are read as “convexes 62C”.

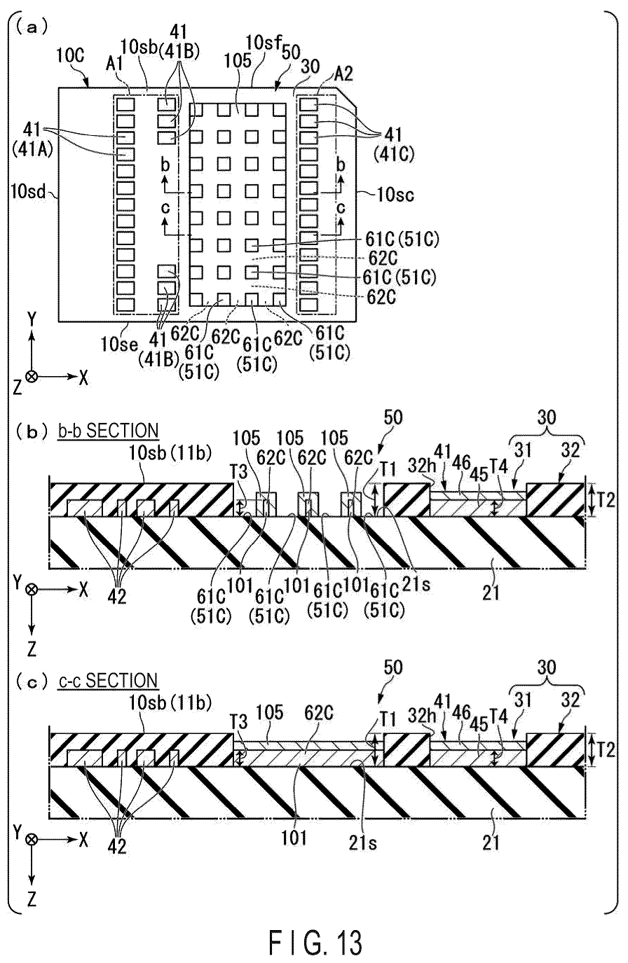

FIG. 13 shows a semiconductor storage device 10C in the third modified example of the first embodiment. The surface layer 30 of the semiconductor storage device 10C includes a plurality of recesses 51C, and thus includes a non-planar part 50 where the concaves 61C and the convexes 62C are alternately arranged. The concaves 61C are the same as the concaves 61B in the second modified example of the first embodiment. The convexes 62C are the same as the convexes 62B in the second modified example of the first embodiment.

In this modified example, a protective film 105 is formed on each convex 62C. The protective film 105 is, for example, a plating layer provided for preventing rust. The protective film 105 is formed of, for example, a metal material, such as gold or nickel. For example, the protective film 105 is formed at the same time as the protective film 46 of each terminal 41 in the process of forming the protective film 46 of each terminal 41. For example, in the process shown in FIG. 12(d), an opening M2h corresponding to the non-planar part 50 is formed in the mask M2, and the plating process is performed, thus forming the protective films 105 at the same time as the protective films 46 of the terminals 41.

According to such a configuration, As in the second modified example of the first embodiment, improvement in heat dissipation can be facilitated. According to the configuration of this modified example, the convexes 62C can be prevented from rusting. Accordingly, the reliability of the semiconductor storage device 10C can be improved.

### Second Embodiment

Next, a second embodiment is described. The second embodiment is different from the first embodiment in that linear recesses are provided. Note that aspects other than those described below are the same as the corresponding configuration points in the first embodiment. In this case, the “concaves 61” are read as “concaves 61D”, and the “convexes 62” are read as “convexes 62D”.

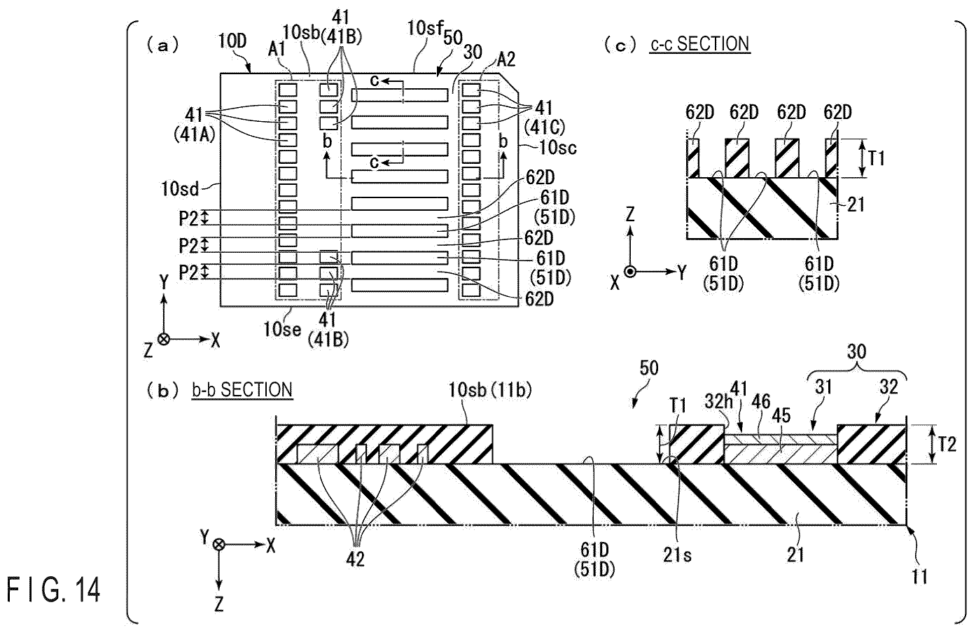

FIG. 14 shows a semiconductor storage device 10D in the second embodiment. In the present embodiment, the surface layer 30 of the semiconductor storage device 10D includes a plurality of recesses 51D, and thus includes a non-planar part 50 where the concaves 61D and the convexes 62D are alternately arranged.

In the present embodiment, the plurality of recesses 51D are apart from each other in the Y-direction, and linearly extend in the X-direction. The recesses 51D are grooves provided in the solder resist layer 32. Each recess 51D reaches a position closer to the insulating base material 21 than a part of the terminal 41 in the Z-direction. For example, the recesses 51 reach the surface 21s of the insulating base material 21.

### (Shape of Concave)

The concaves 61D are formed of the respective recesses 51D. In other words, in the present embodiment, the “concave 61D” may be read as the “recess 51D”. The plurality of concaves 61D are arranged equally in the Y-direction at an interval P2. The width of the concave 61D in the Y-direction is, for example, equivalent to the interval P2 or more. Each recess 61D reaches a position closer to the insulating base material 21 than a part of the terminal 41 in the Z-direction. For example, the concaves 61D reach the surface 21s of the insulating base material 21.

### (Shape of Convex)

The convexes 62D are convexes each formed between two concaves 61D adjacent to each other by providing the concaves 61D. In the present embodiment, each convex 62D is formed between two concaves 61D adjacent to each other in the Y-direction. For example, each convex 62D is a remaining part of the solder resist layer 32 that resides between the corresponding two concaves 61 adjacent to each other. In the present embodiment, the convexes 62D are formed of the same insulating material as that of the solder resist layer 32. In the present embodiment, the thickness T1 of the convex 62D from the surface 21s of the insulating base material 21 is the same as the thickness T2 of the solder resist layer 32 from the surface 21s of the insulating base material 21.

In the present embodiment, the convexes 62D linearly extend in the X-direction. For example, the plurality of convexes 62D are apart from each other in the Y-direction, and linearly extend in the X-direction. Each of the seven convexes 62D described above extends so as to pass adjacent to the plurality of concaves 61D, and across the non-planar part 50. Each of the seven convexes 62D described above extends between both the first area A1 and the second area A2 of the semiconductor storage device 10D.

According to such a configuration, the alternately arranged concaves 61D and convexes 62D increase the heat dissipation area of the semiconductor storage device 10D. This can facilitate improvement in heat dissipation of the semiconductor storage device 10D. In a case of using the thermal conductive sheet 70, a part of the thermal conductive sheet 70 is in contact with the inner surfaces of the concaves 61D, which can increase the contact area between the semiconductor storage device 10D and the thermal conductive sheet 70. This can facilitate further improvement in heat dissipation of the semiconductor storage device 10D.

### First Modified Example of Second Embodiment

Next, a first modified example of the second embodiment is described. This modified example is different from the second embodiment in that a part of each convex is made of a metal material. Note that aspects other than those described below are the same as the corresponding configuration points in the second embodiment. In this case, the “concaves 61D” are read as “concaves 61E”, and the “convexes 62D” are read as “convexes 62E”.

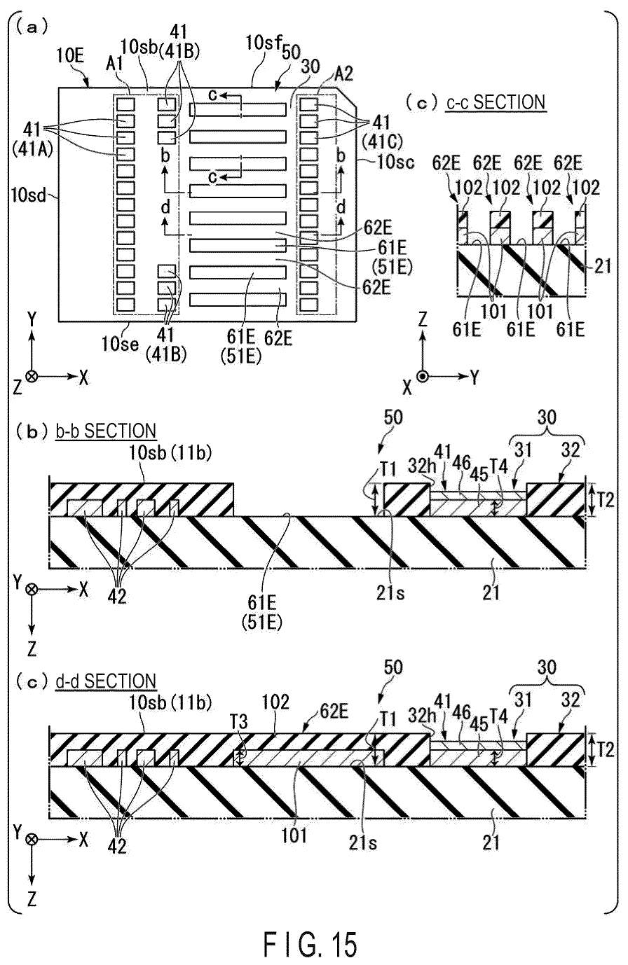

FIG. 15 shows a semiconductor storage device 10E in the first modified example of the second embodiment. The surface layer 30 of the semiconductor storage device 10E includes a plurality of recesses 51E, and thus includes a non-planar part 50 where the concaves 61E and the convexes 62E are alternately arranged. The concaves 61E are the same as the concaves 61D in the second embodiment. As in the first modified example of the first embodiment, each convex 62E includes a first part 101 and a second part 102.

In the present embodiment, the convexes 62E linearly extend in the X-direction. For example, the plurality of convexes 62E are apart from each other in the Y-direction, and extend in the X-direction. Each convex 62E extends so as to pass adjacent to the plurality of concaves 61E, and across the non-planar part 50. Each of the seven convexes 62E extends between both the first area A1 and the second area A2 of the semiconductor storage device 10E.

According to such a configuration, because of a reason similar to that of the first modified example of the first embodiment, improvement in heat dissipation of the semiconductor storage device 10E can be facilitated.

### Second Modified Example of Second Embodiment

Next, a second modified example of the second embodiment is described. This modified example is different from the second embodiment in that the entire convexes are made of a metal material. Note that aspects other than those described below are the same as the corresponding configuration points in the second embodiment. In this case, the “concaves 61D” are read as “concaves 61F”, and the “convexes 62D” are read as “convexes 62F”.

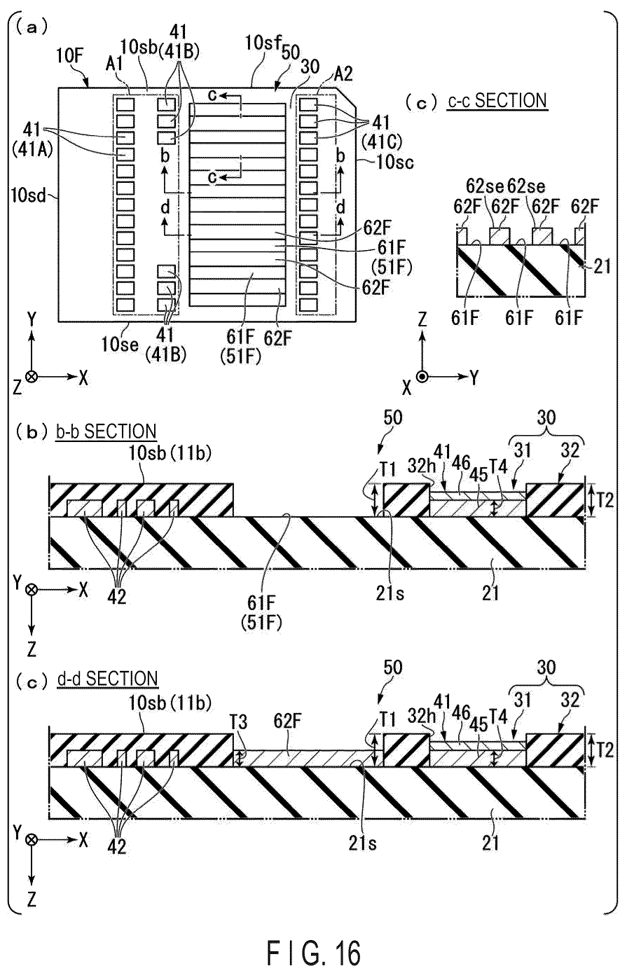

FIG. 16 shows a semiconductor storage device 10F in the second modified example of the second embodiment. The surface layer 30 of the semiconductor storage device 10F includes a plurality of recesses 51F, and thus includes a non-planar part 50 where the concaves 61F and the convexes 62F are alternately arranged. The concaves 61F are the same as the concaves 61D in the second embodiment. The convexes 62F are formed of the same metal material as that of at least a part of the terminals 41. For example, the convexes 62F are formed of the same metal material (e.g., copper) as that of the main bodies 45 of the terminals 41. The thickness T3 of each convex 62F in the Z-direction is, for example, the same as the thickness T4 of the main body 45 of each terminal 41 in the Z-direction. The convexes 62F are formed at the same time as the main bodies 45 of the terminals 41 and the plurality of wires 42 in the process of forming the main bodies 45 of the terminals 41 and the plurality of wires 42. In the present embodiment, the convexes 62F linearly extend in the X-direction. For example, the plurality of convexes 62F are apart from each other in the Y-direction, and linearly extend in the X-direction.

According to such a configuration, because of a reason similar to that of the second modified example of the first embodiment, improvement in heat dissipation of the semiconductor storage device 10F can be facilitated.

### Third Embodiment

Next, a third embodiment is described. The third embodiment is different from the first embodiment in that a plurality of protrusions 111 are provided. Note that aspects other than those described below are the same as the corresponding configuration points in the first embodiment. In this case, the “concaves 61” are read as “concaves 61G”, and the “convexes 62” are read as “convexes 62G”.

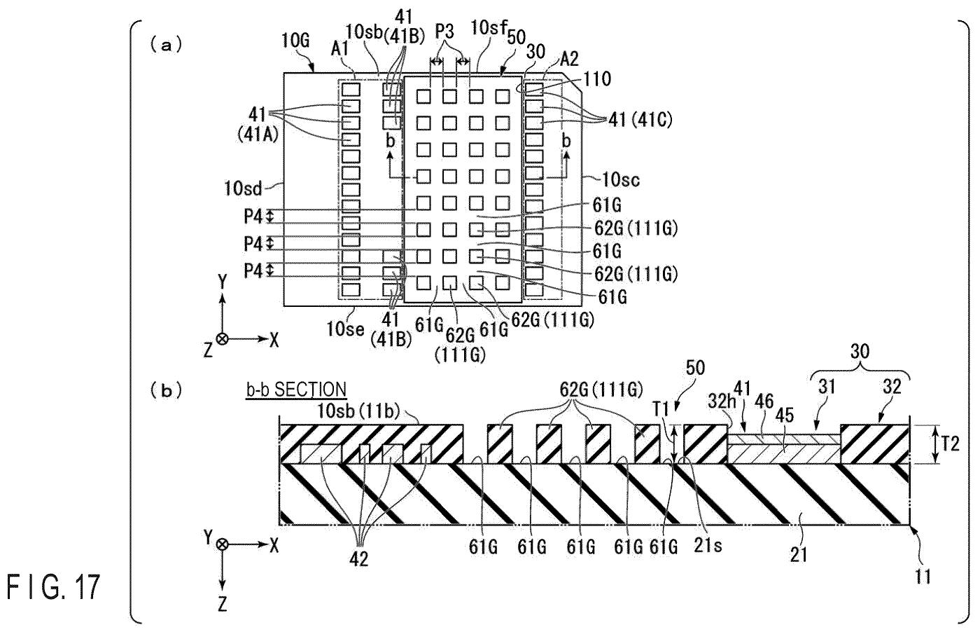

FIG. 17 shows a semiconductor storage device 10G in the third embodiment. In the present embodiment, the surface layer 30 of the semiconductor storage device 10G includes a plurality of protrusions 111, and thus includes a non-planar part 50 where the concaves 61G and the convexes 62G are alternately arranged.

For example, the non-planar part 50 includes a recess 110 and the plurality of protrusions 111. The recess 110 is provided between the first area A1 and the second area A2. The recess 110 sinks with respect to the first area A1 and the second area A2 in the direction approaching the insulating base material 21. The recess 110 reaches a position closer to the insulating base material 21 than a part of the terminal 41 in the Z-direction. For example, the recess 110 reaches the surface 21s of the insulating base material 21 (e.g., the surface of the core material 21A).

The plurality of protrusions 111 are provided in the recess 110. Each protrusion 111 is a columnar protrusion that protrudes in the Z-direction in the recess 110. For example, each protrusion 111 protrudes from the surface 21s of the insulating base material 21 in the direction away from the insulating base material 21. The plurality of protrusions 111 are arranged in a matrix manner including, for example, four rows in the X-direction and eight rows in the Y-direction. In the present embodiment, the plurality of recesses 111 described above are provided, which allows the non-planar part 50 to have an irregular structure where the concaves 61G and the convexes 62G are alternately arranged. For example, the concaves 61G and the convexes 62G are alternately arranged in the X- and Y-directions.

### (Shape of Convex)

The convexes 62G are formed of the protrusions 111. In other words, in the present embodiment, the “convexes 62G” may be read as the “protrusions 111”. The plurality of convexes 62G are arranged equally in the X-direction at an interval P3. The width of each convex 62G in the X-direction is, for example, equal to or less than the interval P3. The width of the convex 62G in the X-direction is, for example, smaller than the width of the terminal 41 in the X-direction. The plurality of convexes 62G are arranged equally in the Y-direction at an interval P4. The width of each convex 62G in the Y-direction is, for example, equal to or less than the interval P4. The width of the convex 62G in the Y-direction is, for example, smaller than the width of the terminal 41 in the Y-direction. Note that the width of the convex 62G in the X-direction may be larger than the width of the terminal 41 in the X-direction. The width of each convex 62G in the Y-direction may be larger than the width of the terminal 41 in the Y-direction.

In the present embodiment, all the convexes 62G are formed of the same insulating material as that of the solder resist layer 32. In the present embodiment, the thickness T1 of each convex 62G from the surface 21s of the insulating base material 21 is the same as the thickness T2 of the solder resist layer 32 from the surface 21s of the insulating base material 21. The convex 62G has a polygonal shape when viewed from the Z-direction. For example, each convex 62G has a quadrangular shape when viewed from the Z-direction. Note that the convex 62G may have a polygonal shape, such as of triangular or pentagonal or more, or a circular shape.

### (Shape of Concave)

Each concave 61G is a part formed between two convexes 62G adjacent to each other, by providing the convexes 62G. In the present application, a “concave” is a part that sinks with respect to the distal surface of each convex in the direction approaching the insulating base material 21. In the present embodiment, each concave 61G is formed between two convexes 62G adjacent to each other in the X-direction or the Y-direction. Each concave 61G reaches a position closer to the insulating base material 21 than a part of the terminal 41. For example, the concaves 61G reach the surface 21s of the insulating base material 21.

In the present embodiment, the concaves 61G are grooves provided in the solder resist layer 32. For example, the concaves 61G linearly extend in the X-direction or the Y-direction. For example, the plurality of concaves 61G include: three concaves 61G that are apart from each other in the X-direction, and extend in the Y-direction; and seven concaves 61G that are apart from each other in the Y-direction, and extend in the X-direction. Each of the three concaves 61G extends so as to pass adjacent to the plurality of convexes 62G, and across the non-planar part 50 in the Y-direction. Each of the seven concaves 61G extends so as to pass adjacent to the plurality of convexes 62G, and across the non-planar part 50 in the X-direction.

According to such a configuration, the alternately arranged concaves 61G and convexes 62G increase the heat dissipation area of the semiconductor storage device 10G. This can facilitate improvement in heat dissipation of the semiconductor storage device 10G. In a case of using the thermal conductive sheet 70, a part of the thermal conductive sheet 70 is in contact with the inner surfaces of the concaves 61G, which can increase the contact area between the semiconductor storage device 10G and the thermal conductive sheet 70. This can facilitate further improvement in heat dissipation of the semiconductor storage device 10G.

### First Modified Example of Third Embodiment

Next, a first modified example of the third embodiment is described. This modified example is different from the third embodiment in that a part of each convex is made of a metal material. Note that aspects other than those described below are the same as the corresponding configuration points in the third embodiment. In this case, the “concaves 61G” are read as “concaves 61H”, and the “convexes 62G” are read as “convexes 62H”.

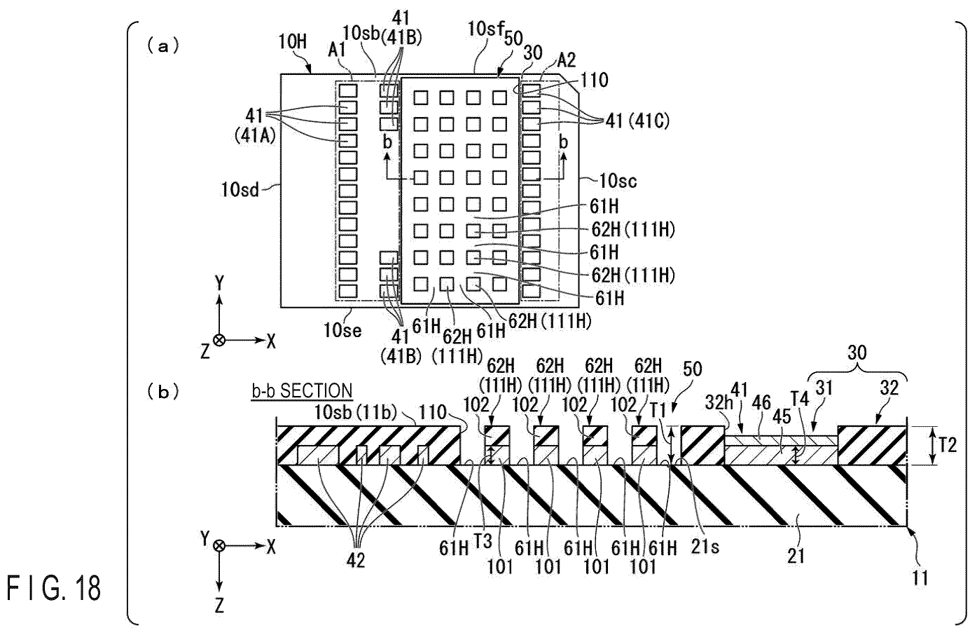

FIG. 18 shows a semiconductor storage device 10H in the first modified example of the third embodiment. The surface layer 30 of the semiconductor storage device 10H includes a plurality of protrusions 111H, and thus includes a non-planar part 50 where the concaves 61H and the convexes 62H are alternately arranged. The concaves 61H are the same as the concaves 61G in the third embodiment. As in the first modified example of the first embodiment, each convex 62H includes a first part 101 and a second part 102.

According to such a configuration, because of a reason similar to that of the first modified example of the first embodiment, improvement in heat dissipation of the semiconductor storage device 10H can be facilitated.

### Second Modified Example of Third Embodiment

Next, a second modified example of the third embodiment is described. This modified example is different from the third embodiment in that the entire convexes are made of a metal material. Note that aspects other than those described below are the same as the corresponding configuration points in the third embodiment. In this case, the “concaves 61G” are read as “concaves 61I”, and the “convexes 62G” are read as “convexes 62H”.

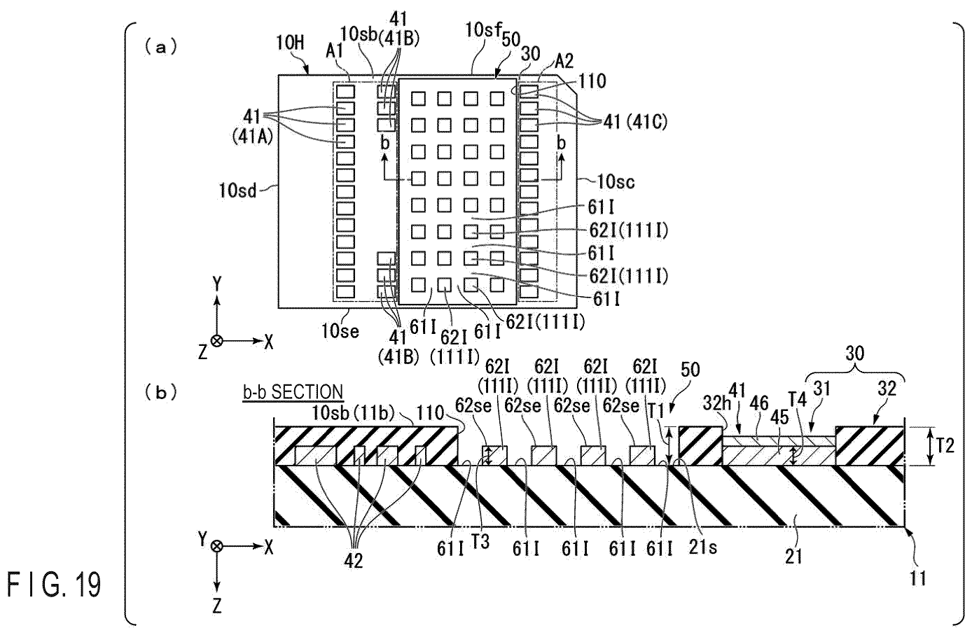

FIG. 19 shows a semiconductor storage device 10I in the second modified example of the third embodiment. The surface layer 30 of the semiconductor storage device 10I includes a plurality of protrusions 111I, and thus includes a non-planar part 50 where the concaves 61I and the convexes 62I are alternately arranged. The concaves 61I are the same as the concaves 61G in the third embodiment. The convexes 62I are formed of the same metal material as that of at least a part of the terminals 41. For example, the convexes 62I are formed of the same metal material (e.g., copper) as that of the main bodies 45 of the terminals 41. The thickness T3 of each convex 62I in the Z-direction is, for example, the same as the thickness T4 of the main body 45 of each terminal 41 in the Z-direction. The convexes 62I are formed at the same time as the main bodies 45 of the terminals 41 and the plurality of wires 42 in the process of forming the main bodies 45 of the terminals 41 and the plurality of wires 42. In this modified example, the convexes 62I are arranged in a matrix manner in the X- and Y-directions.

According to such a configuration, because of a reason similar to that of the second modified example of the first embodiment, improvement in heat dissipation of the semiconductor storage device 10I can be facilitated.

### Fourth Embodiment

Next, a fourth embodiment is described. This embodiment is different from the third embodiment in that linear protrusions are provided. Note that aspects other than those described below are the same as the corresponding configuration points in the third embodiment. In this case, the “concaves 61G” are read as “concaves 61J”, and the “convexes 62G” are read as “convexes 62J”.

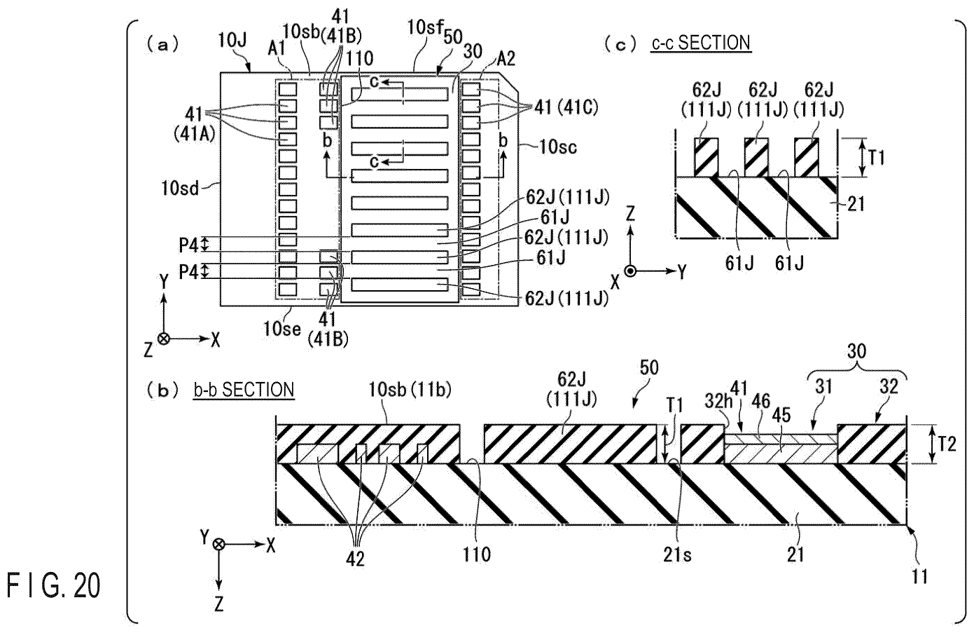

FIG. 20 shows a semiconductor storage device 10J in the fourth embodiment. In the present embodiment, the surface layer 30 of the semiconductor storage device 10J includes the plurality of protrusions 111J, and thus includes a non-planar part 50 where the concaves 61J and the convexes 62J are alternately arranged.

In the present embodiment, the plurality of protrusions 111J are apart from each other in the Y-direction, and linearly extend in the X-direction. Each protrusion 111J is a columnar protrusion that protrudes in the Z-direction in the recess 110. For example, each protrusion 111J protrudes from the surface 21s of the insulating base material 21 in the direction away from the insulating base material 21.

### (Shape of Convex)

The convexes 62J are formed of the protrusions 111J. In other words, in the present embodiment, the “convexes 62J” may be read as the “protrusions 111J”. In the present embodiment, the entire convexes 62J are formed of the same insulating material as that of the solder resist layer 32. In the present embodiment, the thickness T1 of the convex 62J from the surface 21s of the insulating base material 21 is the same as the thickness T2 of the solder resist layer 32 from the surface 21s of the insulating base material 21.

### (Shape of Concave)

The concaves 61J are each formed between two convexes 62J adjacent to each other, by providing the convexes 62J. Each concave 61J reaches a position closer to the insulating base material 21 than a part of the terminal 41 in the Z-direction. For example, the concaves 61J reach the surface 21s of the insulating base material 21. In the present embodiment, the concaves 61J linearly extend in the X-direction. For example, the plurality of concaves 61J are apart from each other in the Y-direction, and linearly extend in the X-direction.

According to such a configuration, the alternately arranged concaves 61J and convexes 62J increase the heat dissipation area of the semiconductor storage device 10J. This can facilitate improvement in heat dissipation of the semiconductor storage device 10J. In a case of using the thermal conductive sheet 70, a part of the thermal conductive sheet 70 is in contact with the inner surfaces of the concaves 61J, which can increase the contact area between the semiconductor storage device 10J and the thermal conductive sheet 70. This can facilitate further improvement in heat dissipation of the semiconductor storage device 10J.

### First Modified Example of Fourth Embodiment

Next, a first modified example of the fourth embodiment is described. This modified example is different from the fourth embodiment in that a part of each convex is made of a metal material. Note that aspects other than those described below are the same as the corresponding configuration points in the fourth embodiment. In this case, the “concaves 61J” are read as “concaves 61K”, and the “convexes 62J” are read as “convexes 62K”.

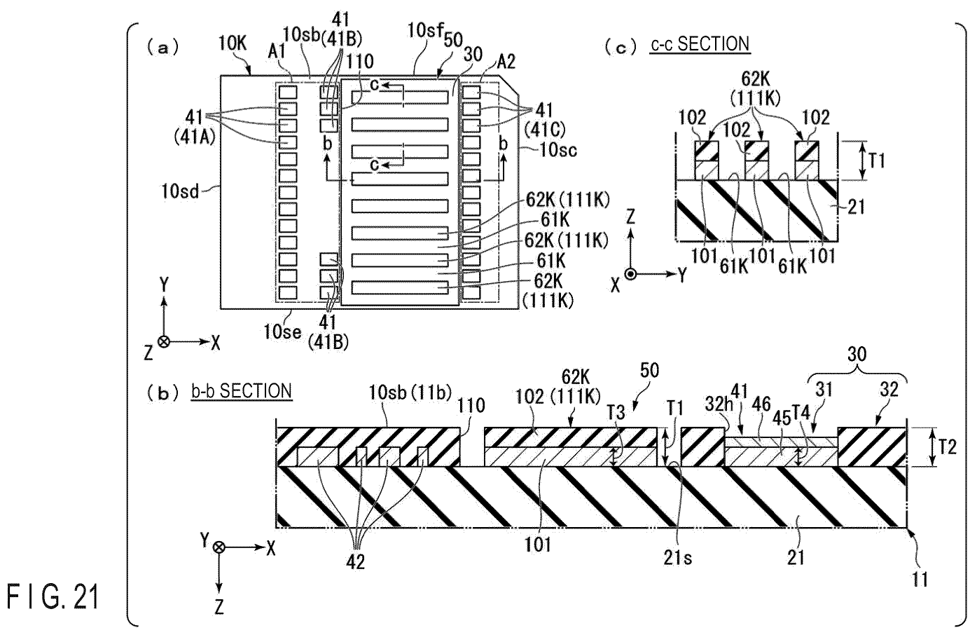

FIG. 21 shows a semiconductor storage device 10K in the first modified example of the fourth embodiment. The surface layer 30 of the semiconductor storage device 10K includes a plurality of protrusions 111K, and thus includes a non-planar part 50 where the concaves 61K and the convexes 62K are alternately arranged. The concaves 61K are the same as the concaves 61J in the fourth embodiment. As in the first modified example of the first embodiment, each convex 62K includes a first part 101 and a second part 102.

In the present embodiment, the convexes 62K linearly extend in the X-direction. For example, the plurality of convexes 62K are apart from each other in the Y-direction, and extend in the X-direction. The convexes 62K extend so as to pass adjacent to the concaves 61K, and across the non-planar part 50. Each of the eight convexes 62K reaches both the first area A1 and the second area A2 of the semiconductor storage device 10K.

According to such a configuration, because of a reason similar to that of the first modified example of the first embodiment, improvement in heat dissipation of the semiconductor storage device 10K can be facilitated.

### Second Modified Example of Fourth Embodiment

Next, a second modified example of the fourth embodiment is described. This modified example is different from the fourth embodiment in that the entire convexes are made of a metal material. Note that aspects other than those described below are the same as the corresponding configuration points in the fourth embodiment. In this case, the “concaves 61J” are read as “concaves 61L”, and the “convexes 62J” are read as “convexes 62L”.

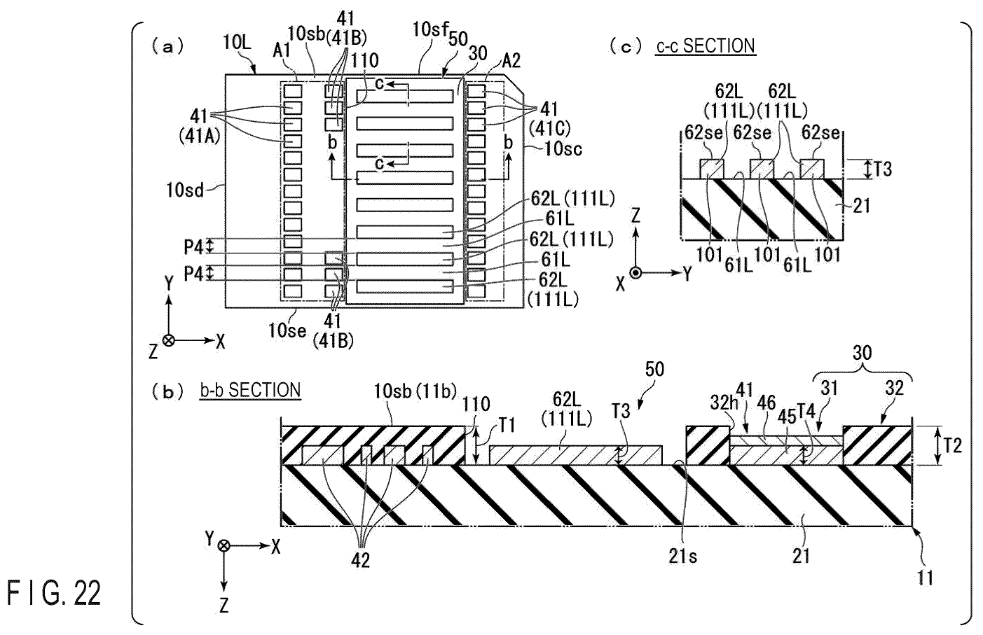

FIG. 22 shows a semiconductor storage device 10L in the second modified example of the fourth embodiment. The surface layer 30 of the semiconductor storage device 10L includes a plurality of protrusions 111L, and thus includes a non-planar part 50 where the concaves 61L and the convexes 62L are alternately arranged. The concaves 61L are the same as the concaves 61J in the fourth embodiment. The convexes 62L are formed of the same metal material as that of at least a part of the terminals 41. For example, the convexes 62L are formed of the same metal material (e.g., copper) as that of the main bodies 45 of the terminals 41. The thickness T3 of each convex 62L in the Z-direction is, for example, the same as the thickness T4 of the main body 45 of each terminal 41 in the Z-direction. The convexes 62L are formed at the same time as the main bodies 45 of the terminals 41 and the plurality of wires 42 in the process of forming the main bodies 45 of the terminals 41 and the plurality of wires 42. In the present embodiment, the convexes 62L linearly extend in the X-direction. For example, the plurality of convexes 62L are apart from each other in the Y-direction, and extend in the X-direction.

According to such a configuration, because of a reason similar to that of the second modified example of the first embodiment, improvement in heat dissipation of the semiconductor storage device 10L can be facilitated.

### Modified Example Common to First to Fourth Embodiments

Next, a modified example common to the first to fourth embodiments is described.

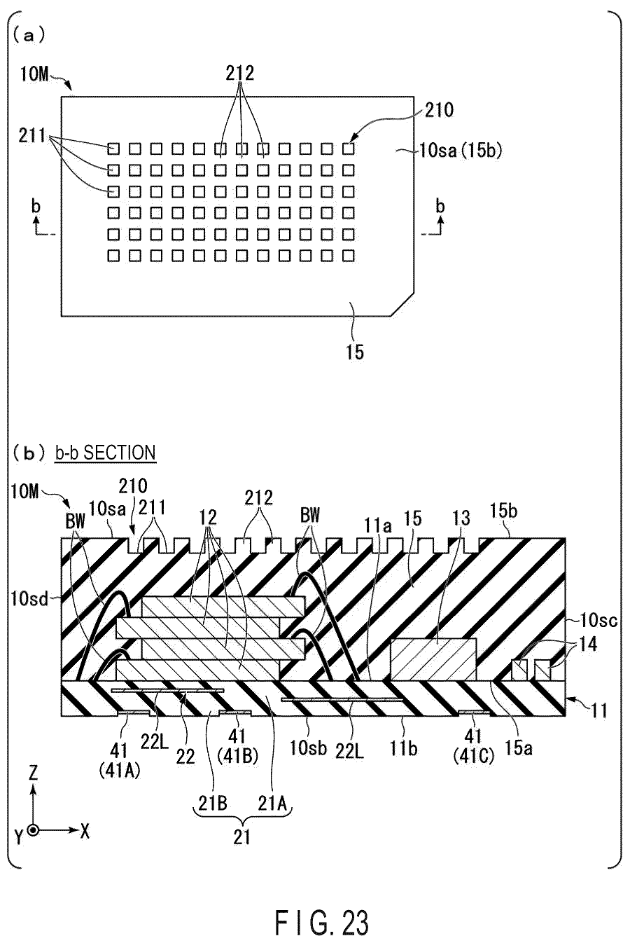

FIG. 23 shows a semiconductor storage device 10M in a modified example of the first to fourth embodiments. In this modified example, the molding resin 15 includes a second surface 15b positioned on the opposite side of the substrate 11. The second surface 15b includes a non-planar part 210 where concaves 211 and convexes 212 are alternately arranged. For example, the concaves 211 and the convexes 212 are alternately arranged in the X- and Y-directions.

The plurality of concaves 211 are arranged equally in the X-direction at regular intervals. The plurality of concaves 211 are arranged equally in the Y-direction at regular intervals. The convexes 212 are each formed between two concaves 211 adjacent to each other by providing the plurality of concaves 211. Each “convex” in the present application means a part protruding in the direction away from the insulating base material 21 in comparison with the bottom of the concave 211. In the present embodiment, the convexes 212 are formed of the same insulating material as that of the molding resin 15.

According to such a configuration, the heat dissipation area of the semiconductor storage device 10M can be further increased. This can facilitate further improvement in heat dissipation of the semiconductor storage device 10M.

The first to fourth embodiments and the modified examples have thus been described above. Note that the embodiments and the modified examples are not limited to the ones described above. For example, the thermal conductive sheet 70 can be omitted. Even in a case of not being combined with the thermal conductive sheet 70, the semiconductor storage device 10 includes the non-planar part 50, and increases the heat dissipation area, which can facilitate improvement in heat dissipation.

The semiconductor storage device 10 is not limited to cases where concaves and convexes are formed by either the plurality of recesses (e.g., recesses 51 to recess 51F) or the plurality of protrusions (e.g., protrusions 111 to 111L). For example, the semiconductor storage device 10 may include both concaves and convexes formed by including both the plurality of recesses (e.g., recesses 51 to recess 51F) and the plurality of protrusions (e.g., protrusions 111 to 111L).

The connector 90 is not limited to the hinge type (or clamshell type) connector. For example, the connector 90 may be a push-pull connector or a push-push connector.

According to at least one of the embodiments described above, the surface layer of the substrate includes the non-planar part which includes at least either the plurality of recesses or the plurality of protrusions on which the concaves and the convexes are alternately arranged in the area outside of the plurality of terminals. Such a configuration can facilitate improvement in heat dissipation.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor storage device, comprising:
a first substrate including a first layer and a second layer on the first layer;
a memory chip on the first layer;
a controller disposed on the first layer and configured to control the memory chip; and
molding resin that covers the first layer, the memory chip, and the controller, wherein
the second layer of the first substrate includes:
a conductive pattern including a plurality of terminals, and
an insulating layer partially covering the conductive pattern and the first layer, and
at a part of the first layer not covered by the insulating layer, one or both of the conductive pattern and the insulating layer form first concaves at predetermined intervals.

2. The semiconductor storage device according to claim 1, wherein the terminals are connectable to a socket-type connector.

3. The semiconductor storage device according to claim 2, further comprising:
a thermal conductive sheet that covers a part of the insulating layer and the first concaves.

4. The semiconductor storage device according to claim 3, wherein
the semiconductor storage device is insertable into a rotatable holder of the connector, such that the terminals are connected to the connector in a state in which the conductive sheet is between the first concaves and a second substrate on which the connector is disposed.

5. The semiconductor storage device according to claim 1, wherein
the first layer is a base layer formed of an insulating material,
the conductive pattern includes wires on the base layer, and
the first concaves reach the base layer.

6. The semiconductor storage device according to claim 1, wherein the insulating layer includes convexes between which one of the first concaves is formed.

7. The semiconductor storage device according to claim 6, wherein the convexes have a polygonal shape or a circular shape when viewed in a thickness direction of the first substrate.

8. The semiconductor storage device according to claim 1, wherein the conductive pattern includes convexes between which one of the first concaves is formed.

9. The semiconductor storage device according to claim 8, wherein the convexes are covered by the insulating layer.

10. The semiconductor storage device according to claim 8, wherein the convexes have a polygonal shape or a circular shape when viewed in a thickness direction of the first substrate.

11. The semiconductor storage device according to claim 1, wherein the first concaves have a polygonal shape or a circular shape when viewed in a thickness direction of the first substrate.

12. The semiconductor storage device according to claim 1, wherein the molding resin includes second concaves along a surface thereof at predetermined intervals.

13. A semiconductor storage unit, comprising:
a first substrate including a first layer and a second layer on the first layer;
a memory chip on the first layer;
a controller disposed on the first layer and configured to control the memory chip;
molding resin that covers the first layer, the memory chip, and the controller; and
a thermal conductive sheet, wherein
the second layer of the first substrate includes:
a conductive pattern including a plurality of terminals, and
an insulating layer partially covering the conductive pattern and the first layer,
at a part of the first layer not covered by the insulating layer, one or both of the conductive pattern and the insulating layer form first concaves at predetermined intervals, and
the conductive sheet covers the first concaves and a part of the insulating layer.

14. The semiconductor storage unit according to claim 13, wherein the conductive sheet has sufficient flexibility such that a part of the conductive sheet enters openings of the first concaves.

15. The semiconductor storage unit according to claim 13, wherein the semiconductor storage unit is a memory card insertable into a socket-type connector.

16. The semiconductor storage unit according to claim 15, wherein
the memory card is insertable into a rotatable holder of the connector, such that the terminals are connectable to terminals of the connector in a state in which the conductive sheet is between the first concaves and a second substrate on which the connector is disposed.

17. The semiconductor storage unit according to claim 13, wherein
the first layer is a base layer formed of an insulating material,
the conductive pattern includes wires on the base layer, and
the first concaves reach the base layer.

18. The semiconductor storage unit according to claim 13, wherein the insulating layer includes convexes between which one of the first concaves is formed.

19. The semiconductor storage unit according to claim 18, wherein the convexes have a polygonal shape or a circular shape when viewed in a thickness direction of the first substrate.

20. The semiconductor storage unit according to claim 13, wherein the conductive pattern includes convexes between which one of the first concaves is formed.
